(19) United States
(12) Patent Application Publication
(10) Pub. No.: US 2012/0280369 A1
(43) Pub. Date: Nov. 8, 2012

(54) METHOD FOR MANUFACTURING SEMICONDUCTOR DEVICE, SUBSTRATE PROCESSING APPARATUS, AND SEMICONDUCTOR DEVICE

(75) Inventors: Tatsuyuki Saito, Toyama-shi (JP); Kazuhiro Yuasa, Takaoka-shi (JP); Yoshiro Hirose, Toyama-shi (JP); Yuji Takebayashi, Toyama-shi (JP); Ryota Sasajima, Toyama-shi (JP); Katsuhiko Yamamoto, Himi-shi (JP); Hirohisa Yamazaki, Toyama-shi (JP); Shintaro Kogura, Toyama-shi (JP); Hirotaka Hamamura, Kodaira-shi (JP)

(73) Assignee: HITACHI KOKUSAI ELECTRIC INC., Tokyo (JP)

(21) Appl. No.: 13/498,020

(22) PCT Filed: Dec. 15, 2010
(86) PCT No.: PCT/JP2010/072558

§ 371 Date: Jun. 15, 2012

(30) Foreign Application Priority Data
Dec. 18, 2009 (JP) 2009-287990
Mar. 24, 2010 (JP) 2010-068372

(51) Int. Cl. C23C 16/52; H01L 29/02; H01L 21/02

(52) U.S. Cl. 257/629; 118/715; 438/761; 257/E21.002; 257/E29.002

(57) ABSTRACT

There is provided a method for manufacturing a semiconductor device, comprising simultaneously or alternately exposing a substrate, which has two or more kinds of thin films having different elemental components laminated or exposed; and performing different modification treatments to the thin films respectively.

### TECHNICAL FIELD

The present invention relates to a method for manufacturing a semiconductor device having a step of processing a substrate, a substrate processing apparatus used for executing this method, and a semiconductor device manufactured by this method or this apparatus.

### DESCRIPTION OF RELATED ART

CVD (Chemical Vapor Deposition) method can be given as one of the techniques of forming a prescribed film on a substrate. The CVD method is a method of forming a film on the substrate, with an element contained in a raw material molecule as a constituent element, by utilizing a reaction of two or more kinds of raw materials in a gas phase or on a surface of the substrate. Further, ALD (Atomic Layer Deposition) method can be given as one of the CVD methods. Two kinds of raw materials used for film formation, are supplied to the substrate alternately one by one, under a certain film forming condition (temperature and time, etc.), which is then adsorbed on the substrate by an atomic layer unit, and a film is formed so as to be controlled by an atomic layer level utilizing a surface reaction. Thus, processing at a lower substrate temperature (processing temperature) is enabled, compared with a conventional CVD method, and a film thickness can be controlled, which is formed by the number of times of a film formation cycle. Further, as a metal film formed on the substrate, for example, a titanium (Ti) film and a titanium nitride (TiN) film can be given. As the other metal film, tantalum (Ta), aluminum (Al), manganese (Mn) and nitride thereof, and Ti, etc., can be given. Further, as an insulating film, for example, oxide and nitride, etc., of hafnium (Hf), zirconium (Zr), and aluminum (Al), being a Hih-k film with a high dielectric constant, can be given.

For example, in order to form a capacitor structure of DRAM, a TiN film, being a lower electrode, a High-k film, being a capacitance insulating film, and a TiN film, being an upper electrode, are laminated using the aforementioned method. The capacitor structure of DRAM is formed by a lamination structure in which the High-k film, being the capacitance insulating film, is interposed between TiN films, being upper and lower electrodes. In order to form the TiN film, for example, titanium-containing gas such as titanium tetrachloride (TiCl₄), and a nitrogen agent (nitrogen-containing gas) such as ammonia (NH₃), are used. Further, in order to form a zirconium oxide film (ZrO film), being the High-k film, raw materials such as tetrakis ethyl methyl amino zirconium (Zr[N(CH₃)CH₂CH₃]₄, abbreviated as TEMAZ), and an oxidizing agent (oxygen-containing gas) such as ozone (O₃) are used. Note that after forming the High-k film, crystallization annealing is applied thereto, to thereby increase a dielectric constant of the High-k film in some cases.

In a case of a strong oxidizing power of an oxidizing agent used for forming the High-k film, the TiN film of the lower electrode and particularly a surface of the TiN film is oxidized. Therefore, Ti oxide having insulation properties is formed on an interface between the TiN film and the High-k film in some cases. Namely, the High-k film and the Ti oxide are connected in series between upper and lower electrodes of a capacitor. Therefore, a capacitor capacitance is reduced in some cases. Reversely, in a case that an oxidizing agent having a weak oxidizing power is used for preventing oxidation of the lower electrode, oxidation of the High-k film becomes insufficient, and the dielectric constant of the High-k film can't be sufficiently increased, thus causing the reduction of the capacitor capacitance to be reduced in some cases.

Further, all raw materials that constitute the High-k film can't be completely oxidized in some cases, due to an insufficient oxidizing power of the oxidizing agent used for forming the High-k film, and an incomplete film forming condition, etc. Further, when the crystallization annealing is performed to the High-k film for the purpose of improving the dielectric constant, oxygen (O) is separated from the High-k film in some cases. In such a case, oxygen in the High-k film is deficient or carbon (C) is remained in the High-k film, thus involving a problem that defect is generated in the High-k film. Then, current flows with such a defect as a route, thus increasing a leak current of the capacitor, or deteriorating the capacitor in some cases. Further, oxygen separated by executing the crystallization annealing, reaches the interface between the High-k film and the TiN film, being a base film, and the Ti oxide is formed on the interface between the TiN film and the High-k film, thus causing the reduction of the capacitor capacitance to occur in some cases.

Thus, the base metal film is also oxidized in some cases, by sufficiently oxidizing the insulating film formed on the metal film. Further, oxidation of the insulating film becomes insufficient in some cases, by suppressing the oxidation of the metal film. Namely, it is difficult to simultaneously perform different modification treatments such as oxidizing the insulating film, and such as suppressing oxidation of the metal film.

### SUMMARY OF THE INVENTION

Therefore, an object of the present invention is to simultaneously perform different modification treatments such as sufficiently oxidizing an insulating film and suppressing oxidation of a metal film, to each of the metal film and the insulating film exposed or laminated on a substrate.

According to an aspect of the present invention, there is provided a method for manufacturing a semiconductor device, comprising:

simultaneously or alternately exposing a substrate having two or more kinds of thin films having mutually different elemental components laminated or exposed, to oxygen-containing gas and hydrogen-containing gas; and simultaneously performing different modification treatments, to the thin films respectively.

According to other aspect of the present invention, there is provided a method for manufacturing a semiconductor device, comprising:

simultaneously or alternately exposing the substrate having two or more kinds of thin films having mutually different elemental components laminated, to oxygen-containing gas and hydrogen-containing gas; and

simultaneously performing different modification treatments, to an interface between the laminated thin films and each of the thin films that constitute the interface.

According to further other aspect of the present invention, there is provided a substrate processing apparatus, comprising:

a processing chamber in which a substrate is housed, the substrate having two or more kinds of thin films having mutually different elemental components exposed or laminated;

a gas supply system configured to supply oxygen-containing gas and hydrogen-containing gas into the processing chamber;

an exhaust system configured to exhaust inside of the processing chamber; and

a controller configured to control at least the gas supply system and the exhaust system,

wherein the controller is configured to control the gas supply system so that the oxygen-containing gas and the hydrogen-containing gas are simultaneously or alternately supplied into the processing chamber in which the substrate is housed, and different modification treatments are performed to the thin films respectively.

According to further other aspect of the present invention, there is provided a semiconductor device, comprising:

a substrate having two or more kinds of thin films having mutually different elemental components laminated or exposed,

wherein different modification treatments are simultaneously performed to the thin films respectively by simultaneously or alternately exposing the two or more kinds of thin films, to oxygen-containing gas and hydrogen-containing gas.

According to the present invention, different modification treatments such as sufficiently oxidizing the insulating film and such as suppressing oxidation of the metal film, can be simultaneously performed.

### BRIEF DESCRIPTION OF THE DRAWINGS

FIG. 1 is a perspective transparent view of a substrate processing apparatus according to a first embodiment of the present invention.

FIG. 2 is a side cross-sectional view of a treating furnace according to the first embodiment of the present invention.

FIG. 3 is an upper side cross-sectional view of the treating furnace according to the first embodiment of the present invention.

FIG. 4 is a flowchart of substrate processing steps according to the first embodiment of the present invention.

FIG. 5 is a timing chart of a gas supply in the substrate processing steps according to the first embodiment of the present invention.

FIG. 6A is an expanded view of an essential part of a wafer before modification treatment, and FIG. 6B is a partial expanded view of FIG. 6A.

FIG. 7 is an expanded view of the essential part of the wafer after modification treatment.

FIG. 8 is a timing chart of the gas supply in the substrate processing steps according to a second embodiment of the present invention.

FIG. 9 is a timing chart of the gas supply of the modification treatment according to the second embodiment of the present invention.

FIG. 10 is a schematic block diagram of a gas supply system according to a third embodiment of the present invention.

FIG. 11 is an upper side cross-sectional view of a nozzle according to a third embodiment of the present invention.

FIG. 12 is a perspective expanded view of a reaction tube according to a fourth embodiment of the present invention.

FIG. 13 is an upper side cross-sectional view of a reaction tube according to a fourth embodiment of the present invention.

FIG. 14 is a side cross-sectional view of a treating furnace according to a fifth embodiment of the present invention.

FIG. 15 is a flowchart of the substrate processing steps including a modification treatment according to sixth and seventh embodiments of the present invention.

FIG. 16 is a timing chart of the gas supply in the substrate processing steps including the modification treatment according to the sixth embodiment of the present invention.

FIG. 17 is a timing chart of the gas supply in the substrate processing steps including the modification treatment according to the seventh embodiment of the present invention.

FIG. 18 is a timing chart of the gas supply in the substrate processing steps including the modification treatment according to an eight embodiment of the present invention.

FIG. 19 is a horizontal cross-sectional view of the treating furnace according to other embodiment of the present invention.

FIG. 20 is a schematic view showing a reaction mechanism in which different modification treatments are simultaneously performed to the TiN film and ZrO film respectively.

FIG. 21 is a graph chart showing XPS measurement results of the TiN film after modification treatment.

FIG. 22 is a graph chart showing measurement results of EOT and leak current density of the ZrO film after modification treatment.

### PREFERRED EMBODIMENTS OF THE INVENTION

### First Embodiment of the Present Invention

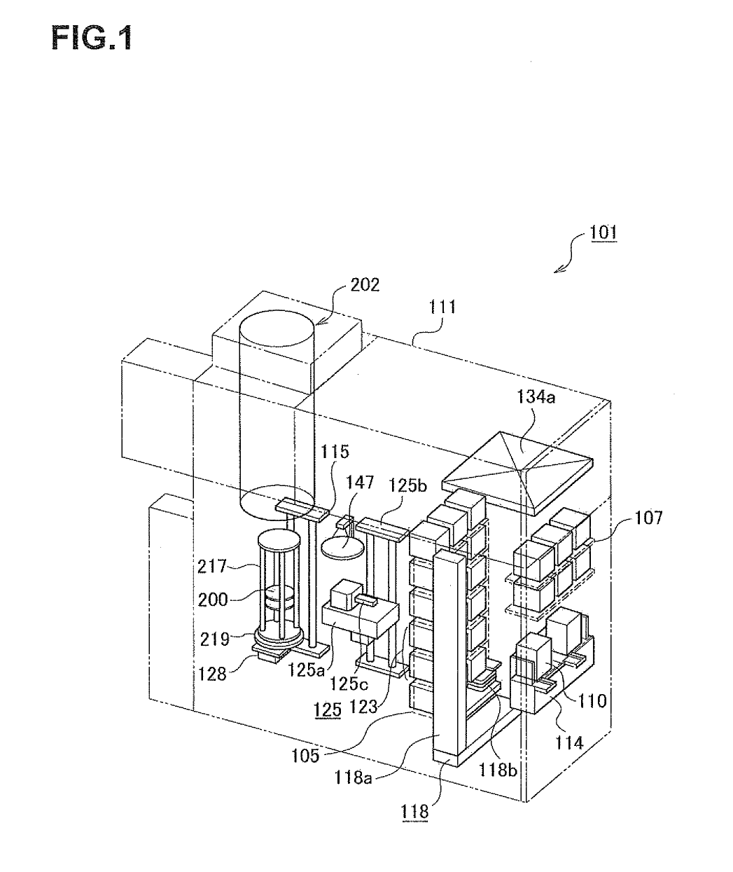

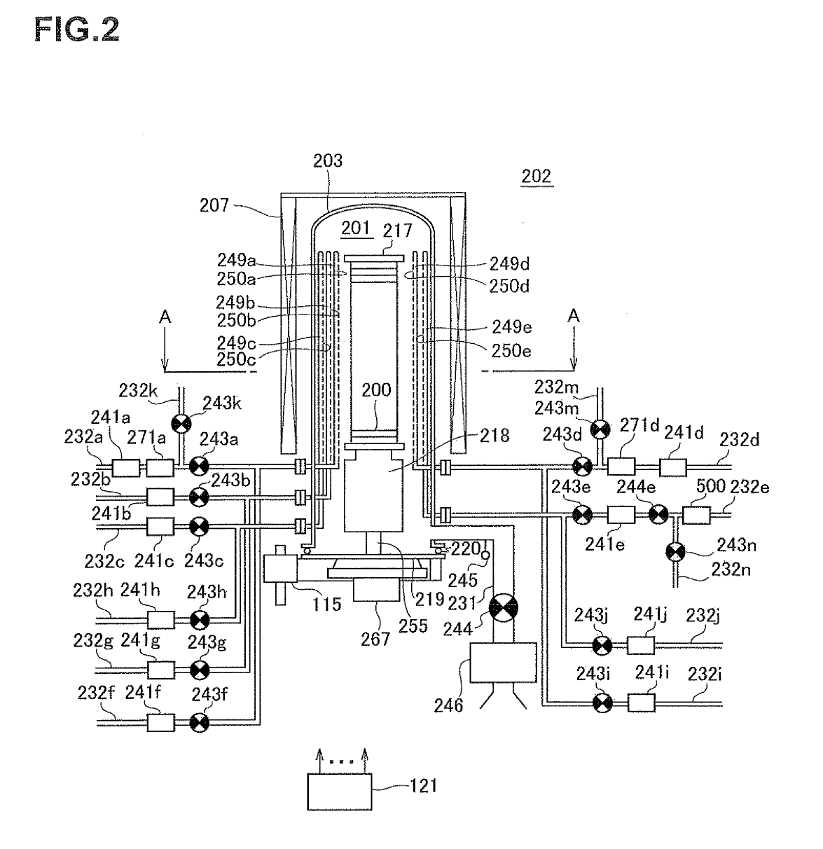

First, a constitutional example of a substrate processing apparatus according to a first embodiment of the present invention will be described, using FIG. 1 to FIG. 3. FIG. 1 is a perspective transparent view of a substrate processing apparatus 101 according to this embodiment. FIG. 2 is a side cross-sectional view of a treating furnace 202 according to this embodiment.

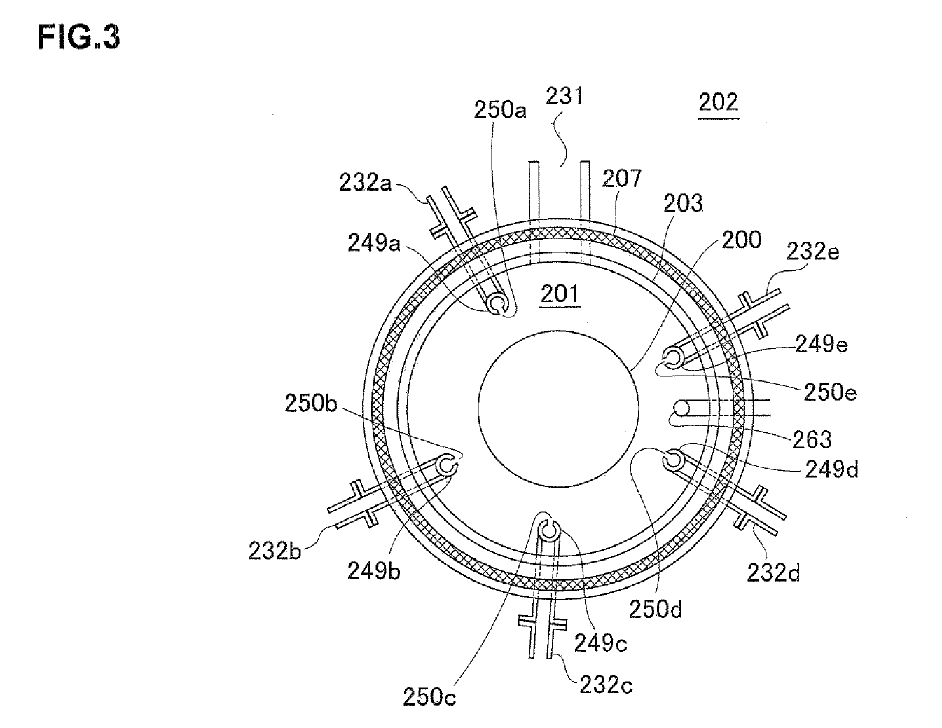

FIG. 3 is an upper side cross-sectional view of the treating furnace 202 according to this embodiment, showing a treating furnace 202 portion taken along the line A-A of FIG. 2.

(Structure of the Substrate Processing Apparatus)

As shown in FIG. 1, the substrate processing apparatus 101 according to this embodiment comprises a housing 111. In order to carry each wafer (substrate) 200 made of silicon, etc., to inside/outside the housing 111, a cassette 110, being a wafer carrying device (substrate housing vessel) for housing a plurality of wafers 200, is used. A cassette stage (substrate housing vessel transfer table) 114 is provided frontward inside the housing 111 (right side in the figure). The cassette 110 is placed on the cassette stage 114 by an in-step carrying device not shown, and is unloaded to outside the housing 111 from the cassette stage 114.

The cassette 110 is placed on the cassette stage 114 by the in-step carrying device, so that the wafer 200 in the cassette 110 is set in a vertical posture, with a wafer charging/discharging port of the cassette 110 directed upward. The cassette stage 114 is configured so that the cassette 110 is rotated by 90° vertically toward a rear side of the housing 111, and the wafer 200 in the cassette 110 is set in a horizontal posture, and the wafer charging/discharging port of the cassette 110 is directed rearward in the housing 111.

A cassette shelf (substrate housing vessel placement shelf) 105 is installed in approximately a center part in a front-back direction in the housing 111. A plurality of cassettes 110 are stored on the cassette shelf 105 in multiple stages and in multiple rows. A transfer shelf 123 storing the cassette 110, being a carrying object of a wafer transfer mechanism 125 as will be described later, is provided on the cassette shelf 105. Further, a preliminary cassette shelf 107 is provided in an upper side of the cassette stage 114, to thereby preliminarily store the cassette 110.

A cassette carrying device (substrate housing vessel carrying device) 118 is provided between the cassette stage 114 and the cassette shelf 105. The cassette carrying device 118 comprises a cassette elevator (substrate housing vessel elevating mechanism) 118a that can be elevated/descended while holding the cassette 110, and a cassette carrying mechanism (substrate housing vessel carrying mechanism), which is a horizontally movable carrying mechanism while holding the cassette 110. The cassette 110 is carried among the cassette stage 114, the cassette shelf 105, the preliminary cassette shelf 107, and the transfer shelf 123, by a coordinated operation of these cassette elevator 118a and cassette carrying mechanism 118b.

A wafer transfer mechanism (substrate transfer mechanism) 125 is provided behind the cassette shelf 105. The wafer transfer mechanism 125 comprises a wafer transfer device (substrate transfer device) 125a capable of horizontally rotating or linearly moving the wafer 200, and a wafer transfer device elevator (substrate transfer device elevating mechanism) 125b capable of elevating the wafer transfer device 125a. In addition, the wafer transfer device 125a comprises a tweezer (substrate transfer jig) 125c for holding the wafer 200 in a horizontal posture. By the coordinated operation of the wafer transfer device 125a and the wafer transfer device elevator 125b, the wafer 200 is charged into a boat (substrate holding tool) 217 as will be described later by being picked-up from the cassette 110 on the transfer shelf 123 (wafer charge), or the wafer 200 is discharged from the boat 217 (wafer discharge) and is stored in the cassette 110 on the transfer shelf 123.

A treating furnace 202 is provided at a rear upper part of the housing 111. An opening (throat) is provided on a lower end of the treating furnace 202, with this opening configured to open/close by a throat shutter (throat open/close mechanism) 147. Note that a structure of the treating furnace 202 will be described later.

A boat elevator (substrate holding tool elevating mechanism) 115, being an elevating mechanism for elevating/descending the boat 217 and carrying it inside/outside the treating furnace 202, is provided in a lower part of the treating furnace 202. An arm 128, being a connection tool, is provided on an elevation platform of the boat elevator 115. A disc-shaped seal cap 219, being a lid member for vertically supporting the boat 217 and air-tightly closing the lower end of the treating furnace 202 when the boat 217 is elevated by the boat elevator 115, is provided on the arm 128 in a horizontal posture.

The boat 217 comprises a plurality of holding members, so that a plurality of (for example, about 50 to 150) wafers 200 are aligned vertically with centers thereof aligned with each other, and held in multiple stages. A detailed structure of the boat 217 will be described later.

A clean unit 134a having a supply fan and a dust-proof filter, is provided above the cassette shelf 105. The clean unit 134a is configured to circulate clean air, being a clean atmosphere, through inside of the housing 111.

Further, the clean unit (not shown) having the supply fan and the dust-proof filter for supplying clean air is installed on a left side end part of the housing 111 on an opposite side to the side of the wafer transfer device elevator 125b and the boat elevator 115. The clean air blown out from the clean unit not shown, is circulated around the wafer transfer device 125a and the boat 217, and thereafter is sucked into an exhaust device not shown, and is exhausted to outside the housing 111.

Next, an operation of the substrate processing apparatus 101 according to this embodiment will be described.

First, the cassette 110 is placed on the cassette stage 114 by the in-step carrying device not shown, so that the wafer 200 is set in a vertical posture and the wafer charging/discharging port of the cassette 110 is directed upward. Thereafter, the cassette 110 is rotated by 90° vertically toward the rear side of the housing 111 by the cassette stage 114. As a result, the wafer 200 in the cassette 110 is set in a horizontal posture, and the wafer charging/discharging port of the cassette 110 is directed rearward in the housing 111.

The cassette 110 is automatically carried and transferred to a designated shelf position of the cassette shelf 105 or the preliminary cassette shelf 107, and temporarily stored therein, and thereafter is transferred to the transfer shelf 123 from the cassette shelf 105 or the preliminary cassette shelf 107, or is directly carried to the transfer shelf 123.

When the cassette 110 is transferred to the transfer shelf 123, the wafer 200 is picked-up from the cassette 110 through the wafer charging/discharging port by the tweezer 125c of the wafer transfer device 125a, and is charged into the boat 217 behind the transfer chamber 124 by the coordinated operation of the wafer transfer device 125a and the wafer transfer device elevator 125b (wafer charge). The wafer transfer mechanism 125 that transfers the wafer 200 to the boat 217, returns to the cassette 110 so that the next wafer 200 is charged into the boat 217.

When previously designated number of wafers 200 are charged into the boat 217, the lower end of the treating furnace 202 closed by the throat shutter 147 is opened by the throat shutter 147. Subsequently, by elevating the seal cap 219 by the boat elevator 115, the boat 217 holding a wafer 200 group is loaded into the treating furnace 202 (boat loading). After boat loading, arbitrary processing is executed to the wafer 200 in the treating furnace 202. Such a processing will be described later. After processing, the wafer 200 and the cassette 110 are discharged to outside of the housing 111 by a reversed procedure to the aforementioned procedure.

(Structure of a Treating Furnace)

Subsequently, the structure of a vertical treating furnace 202 according to this embodiment, will be described.

As shown in FIG. 2, the treating furnace 202 has a heater 207, being a heating unit (heating mechanism). The heater 207 has a cylindrical shape, and is vertically installed by being supported by a heater base (not shown) as a holding plate. Note that the heater 207 also functions as an activating mechanism for activating gas by heat as will be described later.

A reaction tube 203 that forms a reaction vessel (processing vessel) so as to be concentric with the heater 207, is disposed inside the heater 207. The reaction tube 203 is made of a heat resistant material such as quartz (SiO₂) or silicon carbide (SiC), and is formed in a cylindrical shape with an upper end closed and a lower end opened. A processing chamber 201 is formed in a cylindrical hollow part of the reaction tube 203, in a structure in which the wafer 200, being a substrate, can be housed in a state of being arrange vertically in multiple stages by the boat 217 as will be described later.

Nozzles 249a, 249b, 249c, 249d, and 249e are provided in a lower part of the reaction tube 203 in the processing chamber 201, so as to pass through the reaction tube 203. Downstream ends of gas supply tubes 232a, 232b, 232c, 232d, and 232e are respectively connected to upstream ends of nozzles 249a, 249b, 249c, 249d, and 249e. Thus, five nozzles 249a, 249b, 249c, 249d, 249e, and five gas supply tubes 232a, 232b, 232c, 232d, 232e are provided in the reaction tube 203, so that a plurality of kinds of gases, and at least five kinds of gases can be supplied into the processing chamber 201. Further, as will be described later, inert gas supply tubes 232f, 232g, 232H232i, 232j, etc., are respectively connected to the gas supply tubes 232a, 232b, 232c, 232d, 232e.

The nozzle 249a is provided so as to rise upward in a stacking direction of the wafer 200, extending from a lower part to an upper part of an inner wall of the reaction tube 203, in a disc-shaped space between the inner wall of the reaction tube 203 and the wafer 200. The nozzle 249a is formed as an L-shaped long nozzle. Gas supply holes 250a for supplying gas are formed on a side face of the nozzle 249a. The gas supply holes 250a are opened to face a center of the reaction tube 203. A plurality of gas supply holes 250a are formed extending from the lower part to the upper part of the reaction tube 203, each having the same opening area and provided at the same opening pitch.

The downstream end of the gas supply tube 232a is connected to the upstream end of the nozzle 249a. A mass flow controller (MFC) 241a, being a liquid flow rate control unit (liquid flow rate controller), a vaporizer 271a, being a vaporizing device (vaporizing unit) for generating a first source gas (first vaporized gas) by vaporizing a first liquid source, and a valve 243a, being an open/close valve, are provided on the gas supply tube 232a sequentially from the upstream direction. By opening the valve 243a, the first source gas generated in the vaporizer 271a is supplied into the processing chamber 201 through the nozzle 249a. The upstream end of a vent tube 232k connected to the exhaust tube 231 as will be described later, is connected to the gas supply tube 232a between the vaporizer 271a and the valve 243a. A valve 243k, being an open/close valve, is provided in the vent tube 232k. When the first source gas is not supplied into the processing chamber 201, the first source gas is supplied to the vent tube 232k through the valve 243k. By closing the valve 243a and opening the valve 243k, supply of the first source gas into the processing chamber 201 can be stopped while continuing the generation of the first source gas in the vaporizer 271a. Although a prescribed time is required for stably generating the first source gas, supply/stop of the first source gas into the processing chamber 201 can be switched in a short period of time by switching operation of the valve 243a and the valve 243k. Further, the downstream end of the inert gas supply tube 232f is connected to the gas supply tube 232a on the downstream side of the valve 243a (the side close to the reaction tube 203). The mass flow controller 241f, being the flow rate control unit (flow rate controller), and a valve 243f, being an open/close valve, are provided in the inert gas supply tube 232f sequentially from the upstream direction.

A first gas supply system is constituted mainly by the gas supply tube 232a, the vent tube 232k, valves 243a, 243k, the vaporizer 271a, the mass flow controller 241a, and the nozzle 249a. Further, a first inert gas supply system is constituted mainly by the inert gas supply tube 232f, the mass flow controller 241f, and the valve 243f.

The nozzle 249b is provided so as to rise upward in the stacking direction of the wafer 200, extending from the lower part to the upper part of the inner wall of the reaction tube 203, in the disc-shaped space between the inner wall of the reaction tube 203 and the wafer 200. The nozzle 249b is formed as an L-shaped long nozzle. Gas supply holes 250b for supplying gas are formed on the side face of the nozzle 249b. The gas supply holes 250b are opened to face the center of the reaction tube 203. A plurality of gas supply holes 250b are formed extending from the lower part to the upper part of the reaction tube 203, each having the same opening area at the same opening pitch.

The downstream end of the gas supply tube 232b is connected to the upstream end of the nozzle 249b. A mass flow controller (MFC) 241b, being the flow rate control unit (flow rate controller), and a valve 243b, being the open/close valve are provided in the gas supply tube 232b sequentially from the upstream direction. The downstream end of the inert gas supply tube 232g is connected to the gas supply tube 232b on the downstream side of the valve 243b. A mass flow controller 241g, being the flow rate control unit (flow rate controller), and a valve 243g, being the open/close valve, are provided in the inert gas supply tube 232g sequentially from the upstream direction.

A second gas supply system is constituted mainly by the gas supply tube 232b, the valve 243b, the mass flow controller 241b, and the nozzle 249b. Further, a second inert gas supply system is constituted mainly by the inert gas supply tube 232g, the mass flow controller 241g, and the valve 243g.

The nozzle 249c is provided so as to rise upward in a stacking direction of the wafer 200, extending from the lower part to the upper part of the inner wall of the reaction tube 203, in a disc-shaped space between the inner wall of the reaction tube 203 and the wafer 200. The nozzle 249c is formed as the L-shaped long nozzle. Gas supply holes 250c for supplying gas is formed on aside face of the nozzle 249c. The gas supply holes 250a are opened to face the center of the reaction tube 203. A plurality of gas supply holes 250c are formed extending from the lower part to the upper part of the reaction tube 203, each having the same opening area and provided at the same opening pitch.

The downstream end of the gas supply tube 232c is connected to the upstream end of the nozzle 249c. Amass flow controller (MFC) 241c, being the flow rate control unit (flow rate controller), and a valve 243c, being the open/close valve, are provided on the gas supply tube 232c sequentially from the upstream direction. The downstream end of the inert gas supply tube 232h is connected to the gas supply tube 232c on the downstream side of the valve 243c. A mass flow controller 241h, being the flow rate control unit (flow rate controller), and a valve 243h, being the open/close valve, are provided in the inert gas supply tube 232h sequentially from the upstream direction.

A third gas supply system is constituted mainly by the gas supply tube 232c, valves 243c, the mass flow controller 241c, and the nozzle 249c. Further, a third inert gas supply system is constituted mainly by the inert gas supply tube 232h, the mass flow controller 241h, and the valve 243h.

The nozzle 249d is provided so as to rise upward in a stacking direction of the wafer 200, extending from the lower part to the upper part of the inner wall of the reaction tube 203, in a disc-shaped space between the inner wall of the reaction tube 203 and the wafer 200. The nozzle 249d is formed as the L-shaped long nozzle. Gas supply holes 250d for supplying gas is formed on aside face of the nozzle 249d. The gas supply holes 250d are opened to face the center of the reaction tube 203. A plurality of gas supply holes 250d are formed extending from the lower part to the upper part of the reaction tube 203, each having the same opening area and provided at the same opening pitch.

The downstream end of the gas supply tube 232d is connected to the upstream end of the nozzle 249d. Amass flow controller (MFC) 241d, being the liquid flow rate control unit (liquid flow rate controller), a vaporizer 271d, being the vaporizing device (vaporizing unit) for generating a second source gas (second vaporized gas) by vaporizing a second liquid source, and a valve 243d, being the open/close valve, are provided in the gas supply tube 232d sequentially from the upstream direction. By opening the valve 243d, the second source gas generated in the vaporizer 271d is supplied into the processing chamber 201 through the nozzle 249d. The upstream end of a vent tube 232m connected to the exhaust tube 231 as will be described later, is connected between the vaporizer 271d and the valve 243d on the gas supply tube 232d. A valve 243m, being an open/close valve, is provided in the vent tube 232m. When the second source gas is not supplied into the processing chamber 201, the second source gas is supplied to the vent tube 232m through the valve 243m. By closing the valve 243d and opening the valve 243m, supply of the first source gas into the processing chamber 201 can be stopped while continuing the generation of the second source gas in the vaporizer 271d. Although a prescribed time is required for stably generating the second source gas, supply/stop of the second source gas into the processing chamber 201 can be switched in a short period of time by switching operation of the valve 243d and the valve 243m. Further, the downstream end of an inert gas supply tube 232i is connected to the gas supply tube 232a on the downstream side of the valve 243d (the side close to the reaction tube 203). The mass flow controller 241i, being the flow rate control unit (flow rate controller), and a valve 243i, being the open/close valve, are provided in the inert gas supply tube 232i sequentially from the upstream direction.

A fourth gas supply system is constituted mainly by the gas supply tube 232d, the vent tube 232m, valves 243d, 243m, the vaporizer 271d, the mass flow controller 241d, and the nozzle 249d. Further, a fourth inert gas supply system is constituted mainly by the inert gas supply tube 232i, the mass flow controller 241i, and the valve 243i.

The downstream end of the nozzle 249e is connected to the downstream end of the gas supply tube 232e. The nozzle 249e is provided so as to rise upward in the stacking direction of the wafer 200, extending from the lower part to the upper part of the inner wall of the reaction tube 203, in the disc-shaped space between the inner wall of the reaction tube 203 and the wafer 200. The nozzle 249e is formed as the L-shaped long nozzle. Gas supply holes 250e for supplying gas are formed on the side face of the nozzle 249e. The gas supply holes 250e are opened to face the center of the reaction tube 203. A plurality of gas supply holes 250e are formed extending from the lower part to the upper part of the reaction tube 203, each having the same opening area at the same opening pitch.

The downstream end of the gas supply tube 232e is connected to the upstream end of the nozzle 249e. an ozonizer 232e, being an apparatus for generating ozone (O₃) gas, a valve 244e, amass flow controller (MFC) 241e, being the flow rate control unit (flow rate controller), and a valve 243e, being the open/close valve, are provided in the gas supply tube 232e sequentially from the upstream direction. The upstream side of the gas supply tube 232e is connected to an oxygen gas supply source not shown for supplying oxygen (O₂) gas. O₂ gas supplied to the ozonizer 500 is turned into O₃ gas by the ozonizer 500.

Generated O₃ gas is supplied into the processing chamber 201 through the nozzle 249e by opening the valve 243d. The upstream end of a vent tube 232n connected to an exhaust tube 231 as will be described alter, is connected to the gas supply tube 232e between the ozonizer 500 and the valve 244e. A valve 243n, being the open/close valve is provided in the vent tube 232n, and when O₃ gas is not supplied into the processing chamber 201, the O₃ gas is supplied to the vent tube 232n through the valve 243n. By closing the valve 243e and opening the valve 243n, supply of the gas into the processing chamber 201 can be stopped while continuing generation of the O₃ gas by the ozonizer 500. Although a prescribed time is required for stably generating the O₃ gas, supply/stop of the O₃ gas into the processing chamber 201 can be switched in a short period of time by the switching operation of the valve 243e and the valve 243n. Further, the downstream end of the inert gas supply tube 232j is connected to the gas supply tube 232e on the downstream side of the valve 243e. A mass flow controller 241j, being the flow rate control unit (flow rate controller), and the valve 243j, being the open/close valve, are provided in the inert gas supply tube 232j sequentially from the upstream direction.

A fifth gas supply system is constituted mainly by the gas supply tube 232e, the vent tube 232n, the ozonizer 500, valves 243e, 244e, 243n, the mass flow controller 241e, and the nozzle 249e. Further, a fifth inert gas supply system is constituted mainly by the inert gas supply tube 232j, the mass flow controller 241j, and the valve 243j.

For example, a titanium source gas, namely gas containing titanium (Ti) (titanium-containing gas) is supplied into the processing chamber 201 from the gas supply tube 232a through the mass flow controller 241a, the vaporizer 271a, the valve 243a, and the nozzle 249a, as a first source gas. For example, titanium tetrachloride gas (TiCl₄ gas) can be used as the titanium-containing gas. Note that the first source gas may be set in any one of solid, liquid, gaseous states at a normal temperature, under a normal pressure. However, the first source gas in a liquid state will be described here. There is no necessity for providing the vaporizer 271a in a case that the first source gas is in a gaseous state at a normal temperature, under a normal pressure.

Gas containing nitrogen (N) is supplied into the processing chamber 201 as nitriding gas (nitriding agent) from the gas supply tube 232b, through the mass flow controller 241b, the valve 243b, and the nozzle 249b. For example, ammonium (NH₃) gas can be used as the nitrogen-containing gas. Note that NH₃ gas is the gas containing nitrogen (N) and also containing hydrogen (H) (hydrogen-containing gas), and also is a reducing gas (reducing agent). For example, the gas obtained by adding NH₃ gas to H₂ gas as will be described later, can also be used as the reducing gas, and the NH₃ gas can also be used alone as the reducing gas.

The gas containing hydrogen (H) as the reducing gas (reducing agent) is supplied into the processing chamber 201 from the gas supply tube 232c, through the mass flow controller 241c, the valve 243c, and the nozzle 249c. For example, H₂ gas can be used as the hydrogen-containing gas.

For example, zirconium source gas, namely the gas containing zirconium (Zr) (zirconium-containing gas) is supplied into the processing chamber 201 from the gas supply tube 232d, through the mass flow controller 241d, the vaporizer 271d, the valve 243d, and the nozzle 249d. For example, Tetrakis (ethylmethylamino) zirconium gas (TEMAZ gas) can be used as the zirconium-containing gas. Note that the second source gas may be set in any one of solid, liquid, gaseous states at a normal temperature, under a normal pressure. However, the second source gas in a liquid state will be described here. When the second source gas is in a gaseous state at a normal temperature, under a normal pressure, there is no necessity for providing the vaporizer 271d.

For example, the gas containing oxygen (O) (oxygen-containing gas), and for example O₂ gas is supplied from the gas supply tube 232e. O₂ gas supplied from the gas supply tube 232e is turned into O₃ gas, being an oxidized gas (oxidizing agent), by the ozonizer 500. Generated O₃ gas is supplied into the processing chamber 201 through the valve 244e, the mass flow controller 241e, and the valve 243e. Further, O₂ gas can also be supplied into the processing chamber 201 as oxidized gas (oxidizing agent) without generating O₃ gas by the ozonizer 500.

As purge gas or carrier gas, for example, nitrogen gas (N₂ gas) is supplied into the processing chamber 201 from inert gas supply tubes 232f, 232g, 232h, 232i, and 232j respectively through mass flow controllers 241f, 241g, 241h, 241i, 241j, valves 243f, 243g, 243h, 243i, 243j, gas supply tubes 232a, 232b, 232c, 232d, 232e, and nozzles 249a, 249b, 249c, 249d, 249e.

The exhaust tube 231 for exhausting an atmosphere in the processing chamber 201, is provided in the reaction tube 203. A pressure sensor 245, being a pressure detector (pressure detection part) for detecting a pressure in the processing chamber 201, an APC (Auto Pressure Controller) valve 244, being a pressure adjuster (pressure adjustment part), and a vacuum pump 246, being a vacuum exhaust device, are provided in the exhaust tube 231 sequentially from the upstream direction. The APC valve 244 is the open/close valve capable of carrying out vacuum-exhaust and stop of vacuum-exhaust of the inside the processing chamber 201 by opening/closing the valve, and further capable of adjusting the pressure by adjusting an opening degree of the valve. The pressure inside of the processing chamber can be controlled to be a prescribed pressure (vacuum degree) by properly adjusting the opening degree of the APC valve 244 based on pressure information from the pressure sensor 245, while carrying out vacuum-exhaust by the vacuum pump 246. An exhaust system is constituted mainly by the exhaust tube 231, the APC valve 244, the vacuum pump 246, and the pressure sensor 245.

A seal cap 219, being a throat lid member capable of air-tightly closing a lower end opening of the reaction tube 203, is provided in a lower part of the reaction tube 203. The seal cap 219 is abutted on the lower end of the reaction tube 203 from a vertically lower side. The seal cap 219 is made of metal such as stainless, and is formed in a disc shape. An O-ring 220, being a seal member abutted on the lower end of the reaction tube 203, is provided on an upper surface of the seal cap 219. A rotating mechanism 267 for rotating the boat 217, is installed on an opposite side to the processing chamber 201 of the seal cap 219. A rotation axis 255 of the rotating mechanism 267 is passed through the seal cap 219, and is connected to the boat 217 as will be described later, so that the wafer 200 is rotated by rotating the boat 217. The seal cap 219 is elevated vertically by the boat elevator 115, being the elevating mechanism which is vertically installed outside of the reaction tube 203. Thus, the boat 217 can be loaded and unloaded into/from the processing chamber 201.

The boat 217, being a substrate supporting tool, is made of a heat resistant material such as quartz or silicon carbide, so that a plurality of wafers 200 are arranged in a horizontal posture, with centers thereof aligned with each other, and are supported in multiple stages. The boat 217 is configured to hold three or more and 200 or less wafers 200 for example. Note that an insulation member 218 made of the heat resistant material such as quartz and silicon carbide, is provided in a lower part of the boat 217, so that a heat from the heater 207 is hardly transmitted to the seal cap 219 side. Note that the insulation member 218 may also be constituted by a plurality of insulation plates made of the heat resistant material such as quartz and silicon carbide, and an insulation plate holder for supporting them in a horizontal posture in multiple stages.

A temperature sensor 263 is installed in the reaction tube 203 as a temperature detector (see FIG. 3), so that a temperature in the processing chamber 201 has a desired temperature distribution by adjusting a power supply condition to the heater 207 based on the temperature information detected by the temperature sensor 263. Similarly to the nozzles 249a, 249b, 249c, 249d, 249e, the temperature sensor 263 is formed in the L-shape and is provided along the inner wall of the reaction tube 203.

A controller 121, being a control part (control unit) is connected to mass flow controllers 241a, 241b, 241c, 241d, 241e, 241f, 241g, 241H241i, 241j, valves 243a, 243b, 243c, 243d, 243e, 244f, 243g, 243H243i, 243j, 243k, 243m, 243n, vaporizers 271a, 271d, ozonizer 500, pressure sensor 245, APC valve 244, vacuum pump 246, heater 207, temperature sensor 263, rotating mechanism 267, and boat elevator 115, etc. The controller 121 controls flow rate adjustment operation of each kind of gas by mass flow controllers 241a, 241b, 241c, 241d, 241e, 241f, 241g, 241H241i, 241j, open/close operation of the valves 243a, 243b, 243c, 243d, 243e, 244e, 243f, 243g, 243h, 243i, 243j, 243k, 243m, 243n, vaporizing operation of the liquid source by vaporizers 271a, 271d, generating operation of O₃ gas by the ozonizer 500, pressure adjustment operation by opening/closing the APC valve 244 based on the pressure sensor 245, temperature adjustment operation of the heater 207 based on the temperature sensor 263, start/stop of the vacuum pump 246, rotation speed adjustment operation of the rotating mechanism 267, and elevating operation of the boat elevator 115.

(Substrate Processing Step)

Next, explanation will be given for an example of a sequence in which as one step of the manufacturing steps of a semiconductor device using a treating furnace of the aforementioned substrate processing apparatus, a metal film (metal nitride film) and an insulating film (metal oxide film), being two kinds or more of films having mutually different elemental components are laminated on a substrate, and thereafter different modification treatments are simultaneously performed to the films respectively.

In the example of the sequence, a titanium nitride film (TiN film), being a metal nitride film, is formed on the substrate, using TiCl₄ gas, being a titanium (Ti)-containing gas as a first source gas, and using NH₃ gas, being a nitrogen-containing gas as a nitriding gas (nitriding agent). Thereafter, a zirconium oxide film (ZrO film), being an insulating film is formed on a TiN film, being a lower electrode, using TEMAZ gas, being a zirconium (Zr)-containing gas and an organic metal source gas as a second source gas, and using O₃ gas, being an oxygen-containing gas as an oxidizing gas (oxidizing agent), to thereby form a laminated film of TiN film and ZrO film. Then, by using H₂ gas, being a hydrogen-containing gas as a reducing gas (reducing agent), and using O₂ gas, being an oxygen-containing gas as an oxidizing gas (oxidizing agent), different modification treatments are simultaneously performed to the TiN film and the ZrO film respectively. Specifically, oxidation treatment is performed to the ZrO film, and reduction treatment is performed to the TiN film.

In addition, a thin film such as the aforementioned metal film and the insulating film can be formed by a CVD (Chemical Vapor Deposition) method and an ALD (Atomic Layer Deposition) method, etc. In a case of the CVD method, a plurality of kinds of gases containing a plurality of elements constituting the film are simultaneously supplied, and in a case of the ALD method, a plurality of kinds of gases containing a plurality of elements constituting the film are alternately supplied. Then, by controlling a gas supply flow rate and gas supply time during supply of the gas, and supply conditions such as plasma power used for excitation, a silicon nitride film (SiN film) and a silicon oxide film (SiO film) are formed. In these techniques, for example when the SiN film is formed, supply conditions are controlled so that a composition ratio of the film is set to N/Si≈1.33, which is a stoichiometric composition, and when the SiO film is formed, the composition ratio of the film is set to O/Si≈2, which is a stoichiometric composition.

Meanwhile, the supply conditions can also be controlled so that the composition ratio of the film is a prescribed composition ratio which is different from the stoichiometric composition. Namely, the supply conditions can be controlled so that at least one element of a plurality of elements constituting the film is excessive more than other element, regarding the stoichiometric composition. Thus, the film can be formed while controlling the ratio of a plurality of elements constituting the film, namely controlling the composition ratio of the film. Explanation will be given hereafter for an example of a sequence in which a plurality of kinds of gases containing different kinds of elements, are alternately supplied to thereby form two kinds of films having the stoichiometric compositions laminated thereon, and thereafter the laminated film thus formed is modified.

Note that in this specification, the metal film means a film constituted of electroconductive substances containing metal atoms, including not only a conductive metal film made of metal alone, but also a conductive metal nitride film, a conductive metal oxide film, a conductive metal oxinitride film, a conductive metal composite film, a conductive metal alloy film, and a conductive metal silicide film. Further, the titanium nitride film (TiN film) is a conductive metal nitride film.

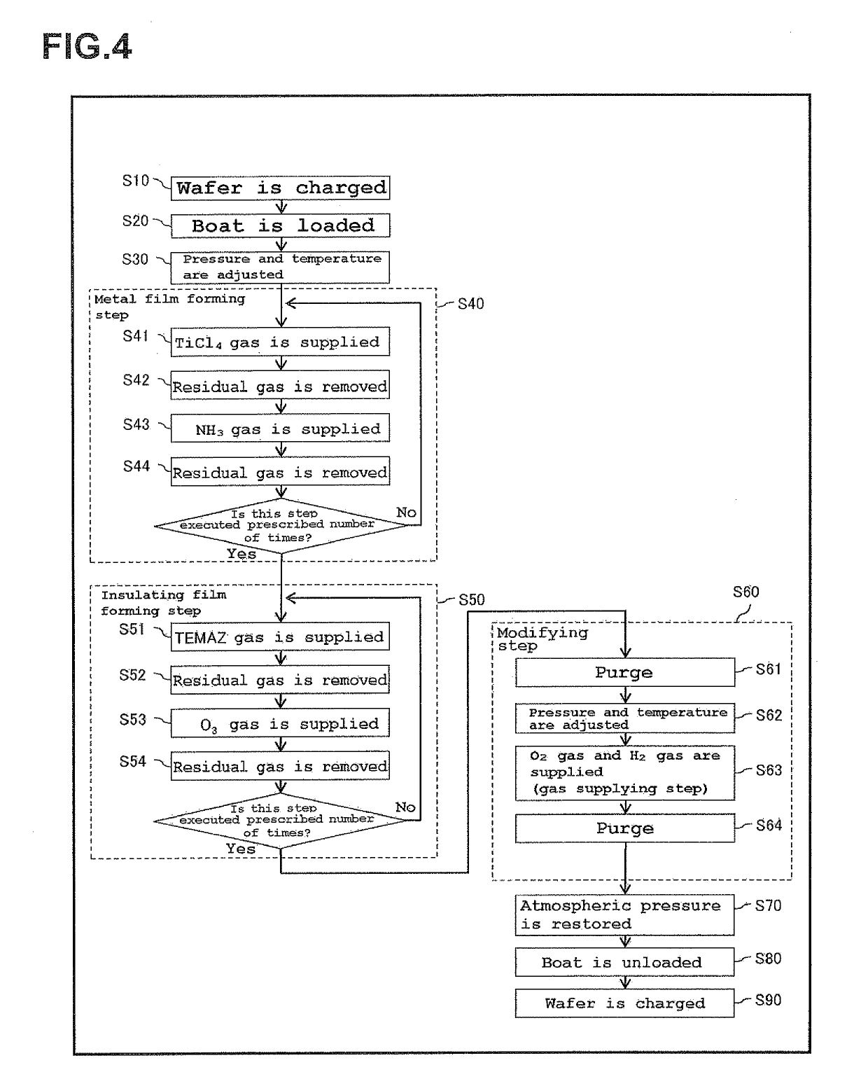

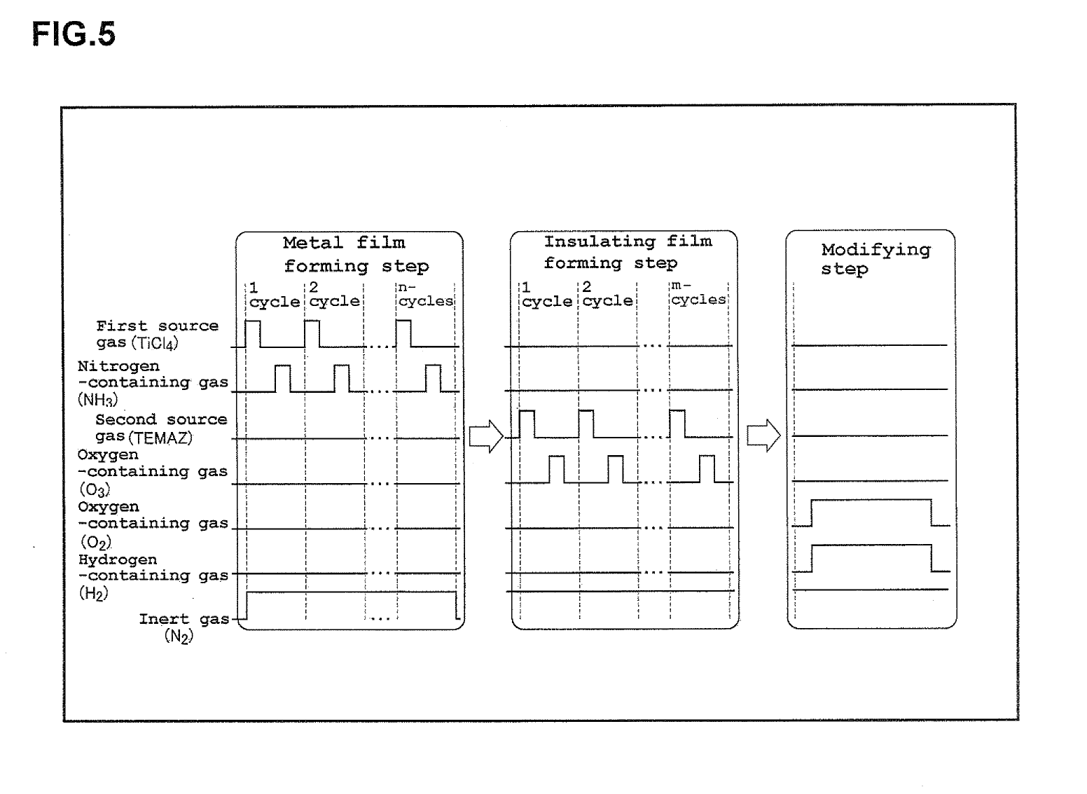

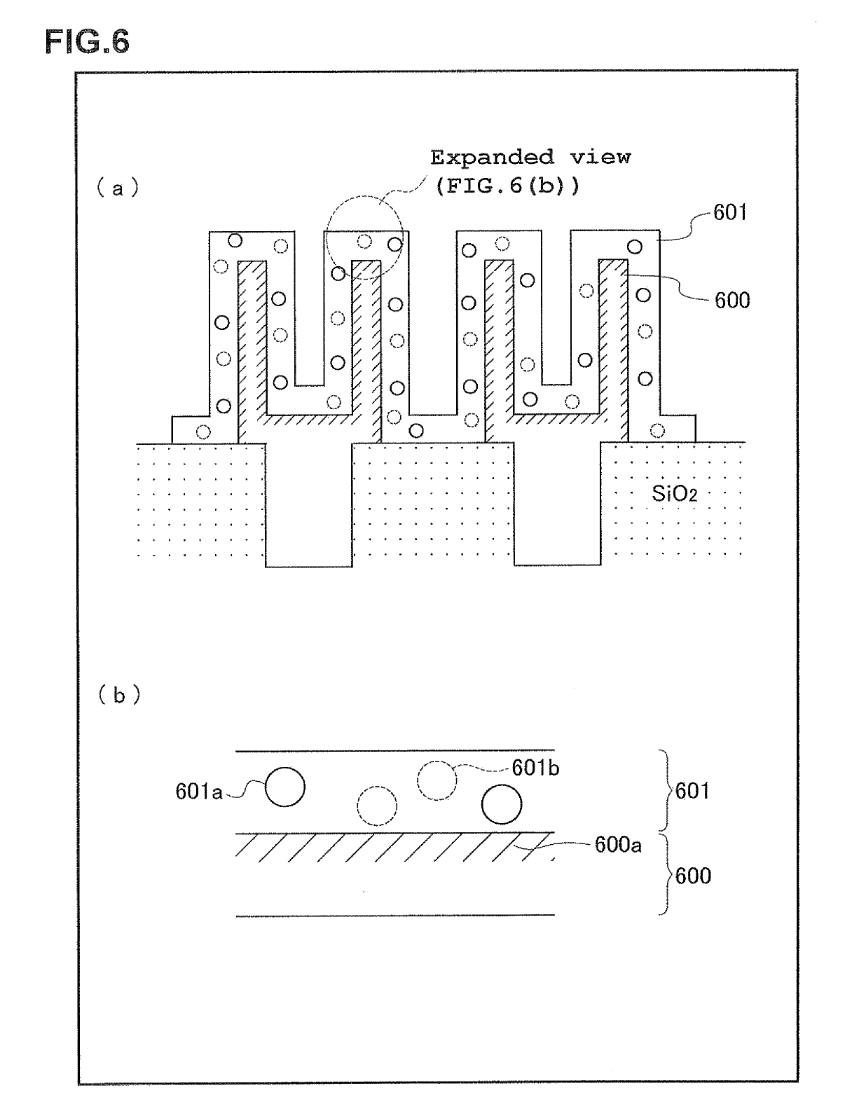

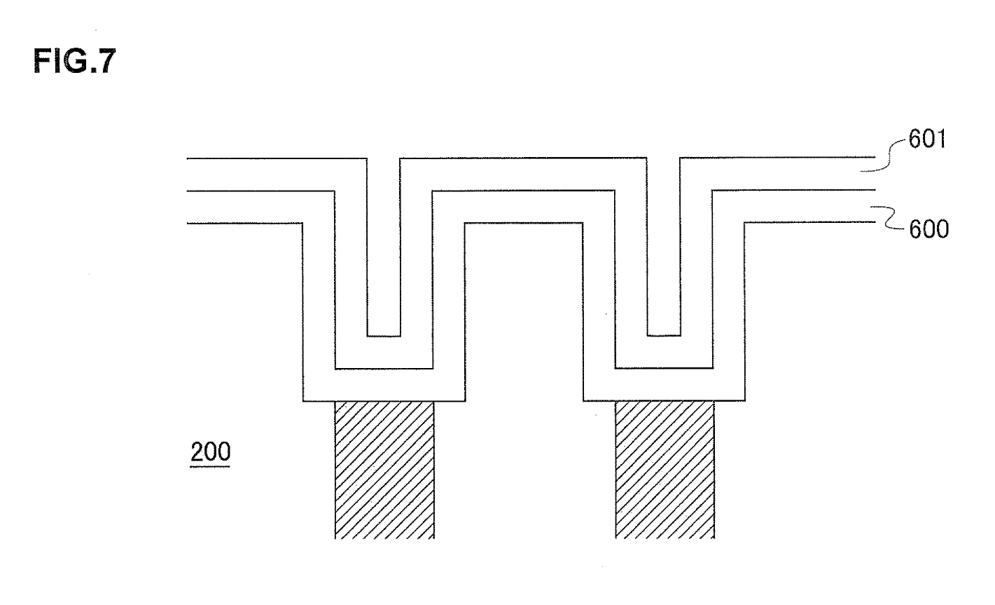

Detailed explanation will be given hereafter, using mainly FIG. 4 to FIG. 7. FIG. 4 is a flowchart of a substrate processing steps including modification treatment according to this embodiment. FIG. 5 is a timing chart of a gas supply in the substrate processing steps including modification treatment according to this embodiment. FIG. 6A is an expanded view of an essential part of the wafer 200 before modification treatment, and FIG. 6B is an expanded view of FIG. 6A. FIG. 7 is an expanded view of the essential part of the wafer 200 after modification treatment. Note that in the explanation given hereafter, an operation of each part constituting the substrate processing apparatus 101 is controlled by the controller 121. Further, in the explanation given hereafter, the film forming processing and the modification treatment of the TiN film and the ZrO film are continuously executed by the same substrate processing apparatus 101 (in-site).

(Wafer Charge S10 and Boat Loading S20)

First, a plurality of wafers 200 are charged into the boat 217 (wafer charge). The number of wafers 200 charged into the boat 217 is 3 or more and 200 or less for example. Then, as shown in FIG. 2, the boat 217 supporting a plurality of wafers 200 is lifted by the boat elevator 115 and is loaded into the processing chamber 201 (boat loading). In this state, the lower end of the reaction tube 203 is in a sealed state by the seal cap 219 through the O-ring 220.

(Pressure/Temperature Adjustment S30)

The inside of the processing chamber 201 is vacuum-exhausted by the vacuum pump 246 so as to be a desired pressure (vacuum degree). At this time, the pressure in the processing chamber 201 is measured by the pressure sensor 245, and based on this measured pressure information, the opening degree of the APC valve 244 is feedback-controlled (pressure adjustment). Further, the inside of the processing chamber 201 is heated by the heater 207 so as to be a desired temperature. At this time, the power supply condition to the heater 207 is feedback-controlled based on the temperature information detected by the temperature sensor 263, so that the inside of the processing chamber 201 has a desired temperature distribution (temperature adjustment). Subsequently, the rotating mechanism 267 is operated, to thereby start rotation of the boat 217 and the wafer 200.

In addition, preferably supply of TiCl₄ to the vaporizer 271a and generation of TiCl₄ gas by the vaporizer 271a are started simultaneously with pressure/temperature adjustment S30, to obtain astable generation amount of the TiCl₄ gas before end of the pressure/temperature adjustment S30 (preliminary vaporization). By adjusting the supply flow rate of the TiCl₄ to the vaporizer 271a by the mass flow controller 241a, the generation amount of the TiCl₄ gas (namely, supply flow rate into the processing chamber 201) can be controlled. The generated TiCl₄ gas is allowed to flow to the vent tube 232k by closing the valve 243a of the gas supply tube 232a and opening the valve 243k of the vent tube 232k.

Further, preferably supply of the TEMAZ to the vaporizer 271d and generation of the TEMAZ gas by the vaporizer 271d are started, simultaneously with the pressure/temperature adjustment S30, to thereby obtain a stable generation amount of the TEMAZ gas before end of the pressure/temperature adjustment S30 (preliminary vaporization). By adjusting the supply flow rate of the TEMAZ to the vaporizer 271d by the mass flow controller 241d, the generation amount of the TEMAZ gas (namely, supply flow rate into the processing chamber 201) can be controlled. The generated TEMAZ gas is allowed to flow to the vent tube 232m by closing the valve 243d of the gas supply tube 232d, and opening the valve 243m of the vent tube 232m.

Further, preferably supply of O₂ gas to the ozonizer 500 and generation of the O₃ gas by the ozonizer 500 are started, simultaneously with the pressure/temperature adjustment S30, to thereby obtain a stable generation amount of the O₃ gas before end of the pressure/temperature adjustment S30 (preliminary generation). The generated O₃ gas is allowed to flow to the vent tube 232n by closing the valve 244e of the gas supply tube 232e and opening the valve 243n of the vent tube 232n.

(Metal Film Forming Step S40)

Next, steps S41 to S44 as will be described later, are set as one cycle, and by performing at least one cycle, the TiN film, being the metal film, is formed on the wafer 200.

<TiCl₄ Gas Supplying Step S41>

The valve 243a of the gas supply tube 232a is opened and the valve 243k of the vent tube 232k is closed in a state that the TiCl₄ gas is stably generated by the vaporizer 271a. The TiCl₄ gas generated by the vaporizer 271a flows through the gas supply tube 232a and is exhausted from the exhaust tube 231 while being supplied into the processing chamber 201 from the gas supply hole 250a of the nozzle 249a. The supply flow rate of the TiCl₄ gas into the processing chamber 201 can be controlled by adjusting the supply flow rate of TiCl₄ to the vaporizer 271a by the mass flow controller 241a. At this time, the valve 243f of the inert gas supply tube 232f is simultaneously opened to flow the inert gas such as N₂ gas. The N₂ gas flowing through the inert gas supply tube 232f is exhausted from the exhaust tube 231 while being supplied into the processing chamber 201 together with the TiCl₄ gas, with its flow rate adjusted by the mass flow controller 241f.

When the TiCl₄ gas flows, the opening degree of the APC valve 244 is suitably adjusted, to obtain a pressure inside of the processing chamber 201 within a range of 40 to 900 Pa. The supply flow rate of the first liquid source (TiCl₄) to the vaporizer 271a controlled by the mass flow controller 241a, is set in a range of 0.05 to 0.3 g/minutes for example. The time required for exposing the wafer 200 to the TiCl₄ gas, namely the time required for supplying gas (irradiation time) is set in a range of 15 to 120 seconds for example. The temperature of the heater 207 at this time is set so that the temperature of the wafer 200 is in a range of 300 to 550° C. for example.

A first layer containing titanium is formed on a base film on the surface of the wafer 200, by supplying the TiCl₄ gas. Namely, a titanium layer (Ti layer), being a titanium-containing layer of less than 1 atomic layer to several atomic layer, is formed on the wafer 200 (on the base film). The titanium-containing layer may be a chemical adsorption (surface adsorption) layer made of TiCl₄. Note that titanium is an element that becomes a solid state by itself. Here, the titanium layer also includes not only a continuous layer made of titanium, but also a discontinuous layer or a thin film formed by overlapped layers thereof. Note that the discontinuous layer made of titanium is called a thin film in some cases. Further, the chemical adsorption layer made of TiCl₄ includes not only a continuous chemical adsorption layer made of TiCl₄ molecules, but also a discontinuous chemical adsorption layer. Note that when a thickness of the titanium-containing layer formed on the wafer 200 exceeds a several atomic layer, a nitriding action in the NH₃ gas supplying step S43 as will be described later, does not reach an entire body of the titanium-containing layer. Moreover, a minimum value of the titanium-containing layer that can be formed on the wafer 200 is less than 1 atomic layer. Therefore, the thickness of the titanium-containing layer is preferably set from less than 1 atomic layer to several atomic layer. Note that by adjusting the condition such as wafer temperature and the pressure in the processing chamber 201, the formed layer can be adjusted so that the titanium layer is formed by depositing titanium on the wafer 200 under a condition that the TiCl₄ gas is self-decomposed, and the chemical adsorption layer made of TiCl₄ gas is formed by chemically adsorbing TiCl₄ on the wafer 200 under a condition that the TiCl₄ gas is not self-decomposed. Note that a film forming rate can be set to be higher in a case that the titanium layer is formed on the wafer 200, than a case that the chemical adsorption layer made of TiCl₄ is formed on the wafer 200. Further, a more dense layer can be formed in a case that the titanium layer is formed on the wafer 200 than in a case that the chemical adsorption layer made of TiCl₄ is formed on the wafer 200.

<Residual Gas Removing Step S42>

After the titanium-containing layer is formed, the valve 243a of the gas supply tube 232a is closed, and the valve 243k of the vent tube 232k is opened, to thereby stop supply of the TiCl₄ gas into the processing chamber 201, and the TiCl₄ gas is allowed to flow to the vent tube 232k. At this time, vacuum-exhaust of the inside of the processing chamber 201 is continued by the vacuum pump 246, with the APC valve 244 of the exhaust tube 231 opened, and the TiCl₄ gas unreacted or after contributing to formation of the titanium-containing layer remained in the processing chamber 201 is removed from the processing chamber 201. Note that at this time, supply of the N₂ gas into the processing chamber 201 is maintained, with the valve 243f opened. Thus, an effect of removing the TiCl₄ gas unreacted or after contributing to the formation of the titanium-containing layer remained in the processing chamber 201, from the processing chamber 201 can be enhanced. As the inert gas, rare gas such as Ar gas, He gas, Ne gas, and Xe gas may be used, in addition to N₂ gas.

<NH₃ Gas Supplying Step S43>

After residual gas in the processing chamber 201 is removed, the valve 243b of the gas supply tube 232b is opened to flow NH₃ gas into the gas supply tube 232b. The flow rate of the NH₃ gas flowing into the gas supply tube 232b is adjusted by the mass flow controller 241b. The NH₃ gas with flow rate adjusted, is exhausted from the exhaust tube 231 while being supplied into the processing chamber 201 from the gas supply hole 250b of the nozzle 249b. At this time, the valve 243g is opened simultaneously, to flow N₂ gas into the inert gas supply tube 232g. The N₂ gas flowing into the inert gas supply tube 232g is exhausted from the exhaust tube 231 while being supplied into the processing chamber 201 together with the NH₃ gas, with its flow rate adjusted by the mass flow controller 241g.

When flowing the NH₃ gas, the APC valve 244 is properly adjusted, to set the pressure in the processing chamber 201 to be the pressure in a range of 40 to 900 Pa for example. A supply flow rate of the NH₃ gas controlled by the mass flow controller 241b is set to be the flow rate within a range of 6 to 15 slm for example. The time required for exposing the wafer 200 to the NH₃ gas, namely a gas supply time (irradiation time) is set to be the time within a range of 15 to 120 seconds for example. The temperature of the heater 207 at this time is set, so that the temperature of the wafer 200 falls within a range of 300 to 550° C. for example.

At this time, only NH₃ gas and N₂ gas are flowed into the processing chamber 201, and TiCl₄ gas is not flowed into the processing chamber 201. Accordingly, the NH₃ gas does not cause a vapor phase reaction, but causes a reaction with a part of a titanium-containing layer, being a first layer formed on the wafer 200, in the TiCl₄ gas supplying step S41. Thus, the titanium-containing layer is nitrided, and is modified to a second layer containing titanium and nitrogen, namely modified to a titanium nitride layer (TiN layer).

<Residual Gas Removing Step S44>

After the titanium-containing layer is modified to the titanium nitride layer, the valve 243b of the gas supply tube 232b is closed, to stop the supply of the NH₃ gas into the processing chamber 201. At this time, vacuum-exhaust of the inside of the processing chamber 201 is continued by the vacuum pump 246, with the APC valve 244 of the exhaust tube 231 opened, so that the NH₃ gas unreacted remained in the processing chamber 201 or after contributing to nitriding, is removed from the processing chamber 201. Note that at this time, supply of the N₂ gas into the processing chamber 201 is maintained, with the valve 243g opened. Thus, an effect of removing the NH₃ gas from the processing chamber 201 can be enhanced, the NH₃ gas being unreacted and remained in the processing chamber 201 or after contributing to nitriding. N₂ gas, NF₃ gas, and N₃H₈ gas, etc., may also be used as the nitrogen-containing gas, in addition to NH₃ gas.

A metal film containing titanium and nitrogen with a prescribed thickness, namely a TiN film can be formed on the wafer 200, by setting the aforementioned steps S41 to S44 as one cycle, and performing this cycle at least once. Note that the aforementioned cycle is preferably repeated multiple number of times.

(Insulating Film Forming Step S50)

Next, a ZrO film, being an insulating film, is formed on the TiN film formed in the metal film forming step S40, by setting steps S51 to S54 as will be described later as one cycle, and performing this cycle at least once.

<TEMAZ Gas Supplying Step S51>

The valve 243d of the gas supply tube 232d is opened, and the valve 243m of the vent tube 232m is closed, in a state that TEMAZ gas is stably generated by the vaporizer 271d. The TEMAZ gas generated by the vaporizer 271d flows through the gas supply tube 232d, and is exhausted from the exhaust tube 231 while being supplied into the processing chamber 201 from the gas supply hole 250d of the nozzle 249d. The supply flow rate of the TEMAZ gas into the processing chamber 201 can be controlled by adjusting the supply flow rate of TEMAZ to the vaporizer 271d by the mass flow controller 241d. At this time, the valve 243i of the inert gas supply tube 232i is opened simultaneously, to flow the inert gas such as N₂ gas. The N₂ gas flowed through the inert gas supply tube 232i is exhausted from the exhaust tube 231 while being supplied into the processing chamber 201 together with the TEMAZ gas, with its flow rate adjusted by the mass flow controller 241i.

When flowing the TEMAZ gas, an opening degree of the APC valve 244 is properly adjusted, and the pressure in the processing chamber 201 is set to the pressure within a range of 50 to 400 Pa for example. The supply flow rate of a second liquid source (TEMAZ) controlled by the mass flow controller 241d is set to the flow rate within a range of 0.1 to 0.5 g/minutes for example. The time required for exposing the wafer 200 to the TEMAZ gas, namely the gas supply time (irradiation time) is set to the time within a range of 30 to 240 seconds for example. At this time, the temperature of the heater 207 is set, so that the temperature of the wafer 200 falls within a range of 150 to 250° C. for example.

By supplying the TEMAZ gas, a third layer containing zirconium is formed on a base film on the surface of the wafer 200 (namely, the TiN film formed in the metal film forming step S40). Namely, a zirconium layer (Zr layer), being a zirconium-containing layer of less than 1 atomic layer to several atomic layer is formed on the TiN film. The zirconium-containing layer may also be a chemical adsorption (surface adsorption) layer of TEMAZ. Note that zirconium is an element, being a solid state by itself. Here, the zirconium layer also includes not only a continuous layer made of zirconium, but also a discontinuous layer or a thin film formed by overlapped layers thereof. In addition, the continuous layer made of zirconium is called a thin film in some cases. Further, the chemical adsorption layer of TEMAZ includes not only a discontinuous chemical adsorption layer made of TEMAZ molecules, but also a discontinuous chemical adsorption layer. Note that when a thickness of the zirconium-containing layer formed on the TiN film exceeds the several atomic layer, an oxidizing action in the O₃ gas supplying step S53 as will be described later, does not reach an entire body of the zirconium-containing layer. Further, a minimum value of the zirconium-containing layer that can be formed on the TiN film is less than 1 atomic layer. Therefore, the thickness of the zirconium-containing layer is preferably set to less than 1 atomic layer to several atomic layer. In addition, by adjusting the condition such as wafer temperature and pressure in the processing chamber 201, formation of the layer can be adjusted, so that the zirconium layer is formed by depositing zirconium on the TiN film under a condition that TEMAZ gas is self-decomposed, and the chemical adsorption layer made of TEMAZ gas is formed by chemically adsorbing TEMAZ on the TiN film under a condition that TEMAZ gas is not self-decomposed. Note that a film forming rate can be increased in a case that the zirconium layer is formed on the TiN film, compared with a case that the chemical adsorption layer made of TEMAZ is formed on the TiN film. Further, a more dense layer can be formed in a case that the zirconium layer is formed on the TiN film than a case that the chemical adsorption layer made of TEMAZ is formed on the TiN film.

<Residual Gas Removing Step S52>

After the zirconium-containing layer is formed, the valve 243 of the gas supply tube 232d is closed, and the valve 243m of the vent tube 232m is opened, to stop the supply of the TEMAZ gas into the processing chamber 201, and flow the TEMAQZ gas to the vent tube 232m. At this time, vacuum-exhaust of the inside of the processing chamber 201 is continued by the vacuum pump 246, with the valve 244 of the APC valve of the exhaust tube 231 opened, to remove the TEMAZ gas from the processing chamber 201, the TEMAZ gas being unreacted and remained in the processing chamber 201 or after contributing to the formation of the zirconium-containing layer. At this time, supply of the N₂ gas into the processing chamber 201 is maintained, with the valve 243i opened. Thus, an effect of removing the TEMAZ gas from the processing chamber 201 can be enhanced, the TEMAZ gas being unreacted and remained in the processing chamber 201 or after contributing to the formation of the zirconium-containing layer. Rare gas such as Ar gas, He gas, Ne gas, and Xe gas may be used as the inert gas, in addition to N₂ gas.

<O₃ Gas Supplying Step S53>

After removing the residual gas in the processing chamber 201, valves 243e and 244e of the gas supply tube 232e are opened, and the valve 243n of the vent tube 232n is closed, in a state that O₃ gas is stably generated by the ozonizer 500. The O₃ gas generated by the ozonizer 500 flows through the gas supply tube 232e, and is exhausted from the exhaust tube 231 while being supplied into the processing chamber 201 from the gas supply hole 250e of the nozzle 249e, with its flow rate adjusted by the mass flow controller 241e. At this time, the valve 243j of the inert gas supply tube 232j is opened simultaneously, to flow the inert gas such as N₂ gas. The N₂ gas flowing through the inert gas supply tube 232j is exhausted from the exhaust tube 231 while being supplied into the processing chamber 201 together with the TEMAZ gas, with its flow rate adjusted by the mass flow controller 241j.

When flowing the O₃ gas, the APC valve is properly adjusted, and the pressure in the processing chamber 201 is set to the pressure within a range of 50 to 400 Pa for example. The supply flow rate of the O₃ gas controlled by the mass flow controller 241e is set to the flow rate within a range of 10 to 20 slm for example. The time required for exposing the wafer 200 to O₃ gas, namely the gas supply time (irradiation time) is set to the time within a range of 60 to 300 seconds for example. Similarly to the TEMAZ gas supplying step S51, the temperature of the heater 207 at this time is set, so that the temperature of the wafer 200 falls within a range of 150 to 250° C. for example.

At this time, only O₃ gas and N₂ gas are flowed into the processing chamber 201, and the TEMAZ gas is not flowed into the processing chamber 201. Accordingly, the O₃ gas does not cause a vapor phase reaction, but causes a reaction with a part of a zirconium-containing layer, being a third layer formed on the TiN film, in the TEMAZ gas supplying step S51. Thus, the zirconium-containing layer is oxidized, and is modified to a fourth layer containing zirconium and oxygen, namely modified to a zirconium oxide layer (ZrO layer). Note that O₂ gas may also be used as oxidized gas (oxidizing agent), in addition to O₃ gas. In this case, generation of O₃ gas by the ozonizer 500 is not performed, and O₂ gas is supplied into the processing chamber 201 as it is.

<Residual Gas Removing Step S54>

After the zirconium-containing layer is modified to the zirconium oxide layer (ZrO layer), valves 243e, 244e of the gas supply tube 232e are closed and the valve 243n of the vent tube 232n is opened, to stop the supply of the O₃ gas into the processing chamber 201, and flow the O₃ gas to the vent tube 232n. At this time, vacuum-exhaust of the inside of the processing chamber 201 is continued by the vacuum pump 246, with the APC valve 244 of the exhaust tube 231 opened, and the O₃ gas unreacted and remained in the processing chamber 201 or after contributing to oxidizing is removed from the processing chamber 201. At this time, supply of the N₂ gas into the processing chamber 201 is maintained, with the valve 243j opened. Thus, an effect of removing the O₃ gas from the processing chamber 201 can be enhanced, the O₃ gas being unreacted and remained in the processing chamber 201 or after contributing to oxidizing.

The insulating film containing zirconium and oxygen with a prescribed film thickness, namely the ZrO film can be formed on the TiN film formed in the metal film forming step S40, by setting the aforementioned steps S51 to S54 as 1 cycle, and performing this cycle at least once. Note that the aforementioned cycle is preferably repeated multiple number of times. The film thickness of the ZrO film is set to 200 nm or less for example.

(Modifying Step S60)

FIG. 6 is a partially expanded view showing a surface of the wafer 200 after executing the metal film forming step S40 and the insulating film forming step S50. As shown in FIG. 6A, a TiN film 600, being the metal film (metal nitride film), and a ZrO film 601, being the insulating film (metal oxide film) are laminated on the wafer 200. In addition, FIG. 6 shows a case that the TiN film 600 is formed as a lower electrode of a capacitor of DRAM, and the ZrO film 601 is formed as a capacitive insulating film.

As shown in the expanded view of FIG. 6B, when the TiN film 600 and the ZrO film 601 are formed by the aforementioned technique, the TiN film 600 is oxidized on an interface portion in contact with the ZrO film 601, by an influence of the O₃ gas, being the oxidized gas (oxidizing agent) used for forming the ZrO film 601, to thereby form an oxide layer 600a in the TiN film 600 in some cases. Further, carbon (C) atoms 601a caused by an organic component of an organic metal source gas (TEMAZ gas) are remained in the ZrO film 601, or oxygen defects 601b caused by oxygen deficiency are generated in some cases.

Therefore, in this embodiment, H₂ gas, being a hydrogen-containing gas as reducing gas (a reducing agent), and O₂ gas, being an oxygen-containing gas as oxidized gas (oxidizing agent), are simultaneously supplied to the wafer 200 on which the TiN film and the ZrO film are exposed or laminated, to thereby execute the modifying step S60 of simultaneously performing different modification treatments to the TiN film and the ZrO film respectively. In the modifying step S60, the following steps S61 to S64 are sequentially executed.

<Purging Step S61>

The APC valve 244 and valves 243f, 243g, 243h, 243i, and 243j are opened while continuing vacuum-exhaust by the vacuum pump 246, with valves 243a, 243b, 243c, 243d, and 243e closed, to supply and exhaust the N₂ gas into the processing chamber 201, and purge the inside of the processing chamber 201 by the N₂ gas. Note that the purging step S61 can be omitted.

<Pressure/Temperature Adjusting Step S62>

When purge of the inside of the processing chamber 201 is completed, the opening degree of the APC valve 244 is adjusted so that the inside of the processing chamber 201 is set to a desired pressure (vacuum degree). Then, a power supply condition to the heater 207 is feedback-controlled so that the inside of the processing chamber 201 is set to a desired temperature. Then, rotations of the boat 217 and the wafer 200 are continued by the rotating mechanism 267.

<Gas Supplying Step S63>

O₂ gas, being the oxygen-containing gas, is flowed into the gas supply tube 232e as the oxidized gas (oxidizing agent) by opening the valves 243e and 244e of the gas supply tube 232e. At this time, generation of the O₃ gas by the ozonizer 500 is not performed. The O₂ gas is exhausted from the exhaust tube 231 while being supplied into the processing chamber 201 from the gas supply hole 250e of the nozzle 231, with its flow rate adjusted by the mass flow controller 241e. At this time, the valve 243j is opened, to flow N₂ gas into the inert gas supply tube 232j. The N₂ gas is exhausted from the exhaust tube 231 while being supplied into the processing chamber 201 together with O₂ gas, with its flow rate adjusted by the mass flow controller 241j.

Further, H₂ gas, being the hydrogen-containing gas, is flowed into the gas supply tube 232c as the reducing gas (reducing agent), by simultaneously opening the valve 243c of the gas supply tube 232c. The H₂ gas is exhausted from the exhaust tube 231 while being supplied into the processing chamber 201 from the gas supply hole 250b of the nozzle 249c, with its flow rate adjusted by the mass flow controller 241c. At this time, the valve 243h is simultaneously opened, to flow the inert gas such as N₂ gas into the inert gas supply tube 232h. The N₂ gas flowing through the inert gas supply tube 232h is exhausted from the exhaust tube 231 while being supplied into the processing chamber 201 together with H₂ gas, with its flow rate adjusted by the mass flow controller 241h (supply of O₂ gas+H₂ gas).

Here, in order to simultaneously supply, start and stop of the gas supply are not necessarily identical to each other, and at least apart of each time for supplying O₂ gas and H₂ gas into the processing chamber 201 may be overlapped. Namely, only the other gas may be supplied alone first, or supply of one of the gases is stopped, and thereafter the other gas may be flowed alone.

At this time, the N₂ gas, being the inert gas, may be supplied into the processing chamber 201 through the nozzles 249a and 249d, from the inert gas supply tube 232f and the inert gas supply tube 232i, by opening the valve 243f and the valve 243i. Thus, O₂ gas and H₂ gas can be prevented from flowing backward into the nozzle 249a and the nozzle 249d.

When flowing O₂ gas and H₂ gas into the processing chamber 201, the pressure in the processing chamber 201 is set to the pressure within a range of 50 to 10000 Pa for example by properly adjusting the APC valve 244 as needed. Further, supply flow rates of O₂ gas and H₂ gas controlled by the mass flow controller 241c are adjusted to be the flow rate within a range of 1000 to 5000 sccm of O₂ gas, 1000 to 5000 sccm of H₂ gas, in the gas flow rate ratio of O₂/H₂=0.5 to 2, desirably within a range of 10/9 (H₂ is 1.8 slm when O₂ is 2 slm).

The time required for exposing the wafer 200 to O₂ gas and H₂ gas, namely the gas supply time (irradiation time) is set within a range of 5 to 60 minutes for example. Further, the temperature of the heater 207 at this time is set, so that the temperature of the wafer 200 is set within a range of 400° C. to 550° C. for example. In the modifying step S60, a removing effect of the residual carbons 601a or oxygen defects 601b shown in FIG. 6B can be enhanced in a case that the temperature of the wafer 200 is set to be high. However, there is a possibility that characteristics of the element which are already incorporated on the wafer 200 are deteriorated by exposing the wafer 200 to a high temperature. Therefore, the temperature is determined in a range of not causing the deterioration of the characteristics to occur.

O₂ gas and H₂ gas are thermally activated and reacted by non-plasma under a heated reduced pressure atmosphere, by supplying O₂ gas and H₂ gas into the processing chamber 201 under the aforementioned condition, to thereby generate an oxidized species containing O such as atomic oxygen (reactant (active species) that contributes to oxidation), and a reduced species containing H such as atomic hydrogen (reactant (active species) that contributes to reduction). The service life of the oxygen species and the reduced species can be prolonged to a degree sufficient to reach the wafer 200, by setting the aforementioned modifying condition. Then, the generated oxidized species and reduced species are diffused into a laminated film of the TiN film and the ZrO film, and a modification treatment, being an oxidation treatment, is performed to the ZrO film mainly by the oxidized species. Further, mainly by the reduced species, the modification treatment, being the reduction treatment, is simultaneously performed to an oxide layer (oxide layer 600a of FIG. 6) formed by oxidizing the TiN film on the interface between the TiN film and the ZrO film. Then, reoxidation of the ZrO film by O₂ gas, and reduction of the TiN film (oxide layer) by H₂ gas, can be simultaneously performed by simultaneously supplying proper flow rates of O₂ gas and H₂ gas. Namely, different modification treatments can be simultaneously performed. FIG. 7 is an expanded view of an essential part of the wafer 200 after the modification treatment. The dielectric constant of the ZrO film 601 after modification is 10 or more.

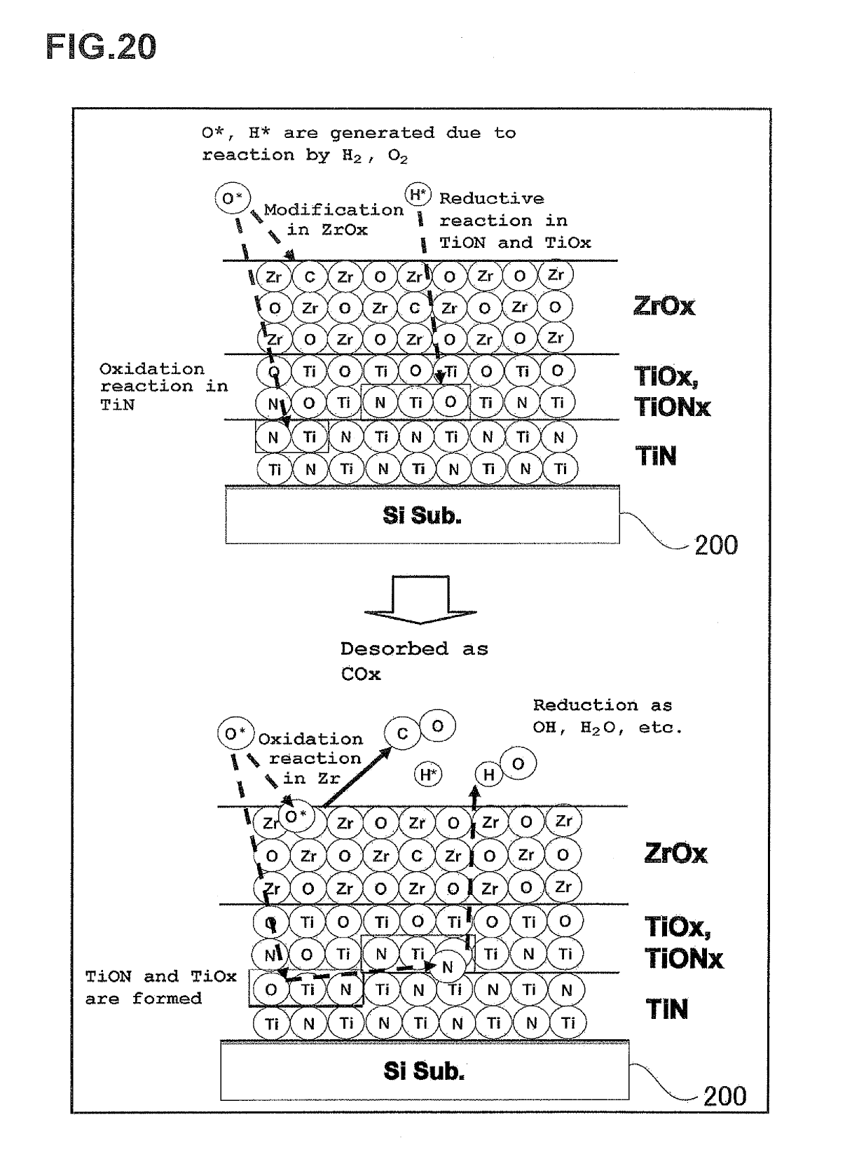

When O₂ gas and H₂ gas are supplied into the processing chamber 201, the oxidized species containing atomic oxygen, etc., and the reduced species containing atomic hydrogen, etc., are simultaneously generated, and therefore an oxidation reaction and a reductive reaction can be simultaneously in progress in each layer. Here, in order to simultaneously perform the different modification treatments (oxidation of the ZrO film and the reduction of the TiN film) to the ZrO film and the TiN film, the flow rate ratio of O₂ gas and H₂ gas need to be adjusted in a prescribed range. If the flow rate ratio is selected to excessively generate the oxidized species (when the flow rate of O₂ gas is excessively increased with respect to H₂ gas) as the flow rate ratio of O₂ gas and H₂ gas, the oxidation reaction is in progress in each film. Similarly, if the flow rate ratio is selected to excessively generate the reduced species as the flow rate ratio of O₂ gas and H₂ gas (when the flow rate of H₂ gas is excessively increased with respect to O₂ gas), the reductive reaction is in progress in each film. Meanwhile, different modification treatments can be simultaneously in progress in the ZrO film and the TiN film by selecting the flow rate ratio to generate prescribed amounts of oxidized species and reduced species respectively (for example, by setting O₂/H₂=0.5 to 2, desirably 10/9 as described above). Explanation will be given for a reaction mechanism of simultaneously advancing the different modification treatments by properly adjusting the flow rate ratio of O₂ gas and H₂ gas, with reference to FIG. 20.

A mechanism of advancing mainly the oxidation reaction in the ZrO film, will be described first. As described above, carbon (C) atoms, etc., caused by an organic component made of organic metal source gas (TEMAZ gas) are remained in the film when the ZrO film is formed by using the organic metal source gas such as TEMAZ gas, and a state including Zr—C bond is generated in the film. A bonding energy between Zr—C is smaller than a bonding energy between C-O (namely, a bonding force of Zr—C is stronger than a bonding force of C-O). Therefore, when the oxidized species is supplied to the ZrO film containing Zr—C bond, Zr—C bond is cut by the oxidized species entered into the film, and C-O bond is formed instead. As a result, the carbon atoms are dissociated from the film as Cox. Then, Zr—O bond is formed after dissociating the carbon atoms, thereby promoting the oxidation of the ZrO film. Note that it can be considered that the reductive reaction is simultaneously in progress in the ZrO film because the reduced species is supplied to the ZrO film. However, ZrO, being a perfect oxide, is relatively hardly reduced. Therefore, the reductive reaction of the ZrO film can be suppressed by adjusting the flow rate ratio of O₂ and H₂ within a prescribed range, and generating a prescribed amount of oxidized species and reduced species (by suppressing a generation ratio of the reduced species within a prescribed range).

Explanation will be given next for a mechanism that the reductive reaction is mainly in progress in the TiN film. Similarly, the bonding energy between Ti—N is smaller than the bonding energy between Ti—O. Therefore, when the oxidized species is supplied to the TiN film mainly composed of Ti—N bond, the Ti—N bond is cut by the oxidized species entered into the film, and TiOx and TiONx are easily formed. However, TiOx and TiONx which are not perfect oxides, are relatively easily reduced, compared with ZrO which is a perfect oxide. Therefore, TiOx and TiONx formed in the TiN film can be reduced, by generating a prescribed amount of reductive species in the processing chamber 201. This is because anatomic radius of hydrogen that constitutes the reductive species is sufficiently small, and therefore hydrogen is easily diffused through the ZrO film, to easily reach the interface between the ZrO film and the TiN film. The oxidized species is also generated in the processing chamber 201, and therefore it can be considered that the oxidation reaction can also be simultaneously in progress in the TiN film. However, in order to supply oxidized species to the TiN film, the oxidized species composed of oxygen with a larger atomic radius than that of hydrogen, is required to reach the TiN film through the ZrO film. Therefore, it can be considered that an amount of the oxidized species supplied to the TiN film can be sufficiently reduced by adjusting the flow rate ratio of O₂ and H₂ within a prescribed range, and generating a prescribed amount of oxidized species and reductive species respectively (by suppressing the generation ratio of the oxidized species), and the oxidation reaction of the TiN film can be suppressed.

Note that O₂ gas and H₂ gas are not limited to a case that they are activated by heat. For example, at least either one of O₂ gas and H₂ gas or both of them can be activated and flowed by plasma. Oxidized species and/or reductive species with higher energy can be generated by activating and flowing O₂ gas and/or H₂ gas by plasma, and an effect of improving the characteristics of a semiconductor device can be obtained by performing modification treatment using the oxidized species and/or reductive species. In addition, in the aforementioned temperature zone, O₂ gas and H₂ gas are activated and sufficiently reacted by heat, thus generating sufficient amounts of oxidized species and reductive species. Therefore, sufficient oxidizing power and reducing power can be obtained even if O₂ gas and H₂ gas are thermally activated by non-plasma. Note that a soft reaction can be caused and a soft modification treatment can be performed by thermally activating and supplying O₂ gas and H₂ gas.

<Purging Step S64>

When the modification treatment is ended, the valve 243e and the valve 243c are closed, to stop supply of O₂ gas and H₂ gas into the processing chamber 201. At this time, supply of N₂ gas into the processing chamber 201 is maintained, with the valve 243j and the valve 243h opened. The N₂ gas actions as a purge gas, thus purging the inside of the processing chamber 201 by inert gas, so that the gas remained in the processing chamber 201 is removed from the processing chamber 201. Note that N₂ gas during modification treatment and purging, may also be supplied using inert gas supply tubes 232g, 232f, and 232i.

<Wafer Discharge S90 from the Atmospheric Pressure Restoring Step S70>

Thereafter, the pressure in the processing chamber 201 is restored to a normal pressure by properly adjusting the opening degree of the APC valve 244 (S70). Then, the seal cap 219 is descended by the boat elevator 115, to open the lower end of the manifold 209 and unload the boat 217 holding the processed wafer 200 to outside of the reaction tube 203 from the lower end of the manifold 209 (S80). Thereafter, the processed wafer 200 is discharged from the boat 217 (wafer discharge) (S90).

(Effect of this Embodiment)

According to this embodiment, H₂ gas, being the hydrogen-containing gas as the reducing gas (reducing agent), and O₂ gas, being the oxygen-containing gas as the oxidized gas (oxidizing agent) are simultaneously supplied to the wafer 200 on which the TiN film and the ZrO film, being two kinds or more films having mutually different elemental components are exposed or laminated. Then, O₂ gas and H₂ gas are reacted under a heated and reduced pressure atmosphere, to thereby generate the oxidized species containing O of atomic oxygen, etc., and the reductive species containing H of atomic hydrogen, etc., and supply these oxidized species and reductive species to the laminated film of the ZrO film and the TiN film. Thus, different modification treatments (oxidation reaction and reductive reaction) can be simultaneously performed to the ZrO film and the TiN film respectively. In the modification treatment (oxidation treatment) of the ZrO film, the energy of the oxidized species is higher than the bonding energy of Zr—C included in the ZrO film. Therefore, Zr—C bond included in the ZrO film is cut-off by giving the energy of the oxidized species to the ZrO film to which the oxidation treatment is applied. Carbon (C) atoms whose bond with zirconium (Zr) atoms is cut-off, are removed from the film and discharged as CO₂, etc. Further, a bond-forming hand of Zr-atom which is excess by cutting the bond with C-atom, is bonded with oxygen (O)-atom included in the oxidized species, to thereby form Zr—O bond. In addition, at this time, the ZrO film becomes more dense. Thus, modification of the ZrO film is performed. Further, in the modification treatment (reduction treatment) of the oxidized layer, the reduced species is diffused through the ZrO film, to reach the interface between the TiN film and the ZrO film, so that the oxide layer formed on the interface can be reduced.

Further, according to this embodiment, different modification treatments can be simultaneously performed to the ZrO film and the TiN film by selecting the flow rate ratio causing prescribed amounts of oxidized species and reductive species to be generated respectively (for example, by setting O₂/H₂=0.5 to 2, desirably 10/9 as described above).

Further, according to this embodiment, O₂ gas and H₂ gas are thermally activated by non-plasma. Thus, the soft reaction can be generated, and the soft modification treatment can be performed.

### Example

In this example, the TiN film and the ZrO film are laminated on the wafer by the same technique as the technique of the aforementioned embodiment, and thereafter different modification treatments are simultaneously performed to the ZrO film and the TiN film using O₂ gas and H₂ gas. Then, a composition of the TiN film after modification treatment (reduction treatment) was measured by X-ray Photoelectron Spectroscopy (abbreviated as XPS). Further, EOT (an equivalent oxide film thickness) and leak current density of the ZrO film after modification treatment (oxidation treatment) were respectively measured. Note that a wafer temperature during the modification treatment was set to 45 to 500° C., and a gas supply time (irradiation time) during the modification treatment was set to 5 to 60 minutes. A voltage applied to the ZrO film during measurement of the EOT and the lead current density was set to −1.0V.

Further, as a reference example, the TiN film and the ZrO film were formed on the wafer by the same technique as the technique of the aforementioned embodiment, and thereafter annealing was applied to these films using N₂ gas. Then, the composition of the TiN film after annealing, and the EOT and the leak current density of the ZrO film after annealing, were respectively measured under the same condition as the condition of the example.

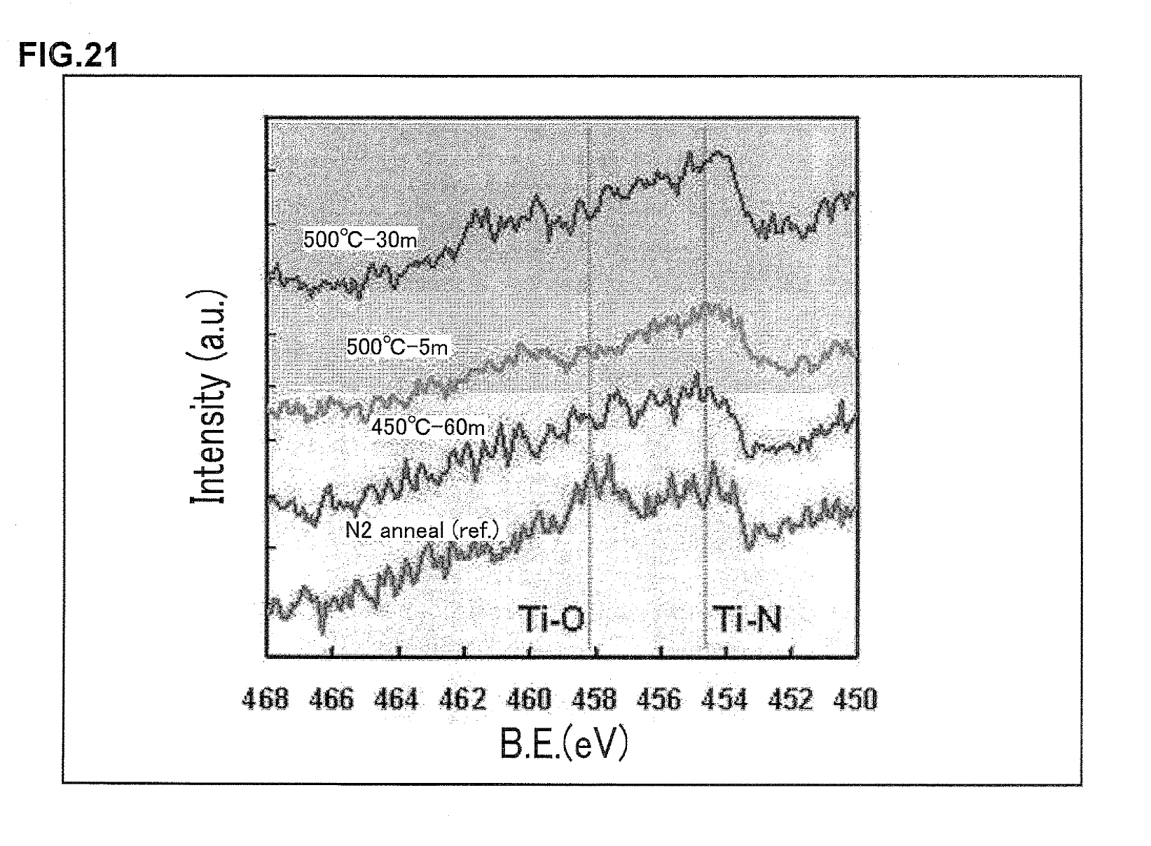

FIG. 21 is a view showing XPS measurement results of the TiN film after the modification treatment (after the reduction treatment) according to this example. Observed energy (eV) of photoelectrons is taken on the horizontal axis, and observed number (arbitrary unit) of photoelectrons is taken on the vertical axis. According to FIG. 21, it is found that a peak is not observed in TiO, which is observed in the TiN film of a reference example (lowermost line) to which annealing is applied using N₂ gas, in any one of the TiN film of the example (uppermost line) in which the wafer temperature during the modification treatment is set to 500° C. and the gas irradiation time is set to 30 minutes, and the TiN film of the example (second line from the top) in which the wafer temperature during the modification treatment is set to 500° C. and the gas irradiation time is set to 5 minutes, and the TiN film of the example (third line from the top) in which the wafer temperature during the modification treatment is set to 450° C. and the gas irradiation time is set to 60 minutes. Namely, it is found that TiO formed on the interface between the TiN film and the ZrO film is effectively reduced by performing the aforementioned modification treatment using O₂ gas and H₂ gas.

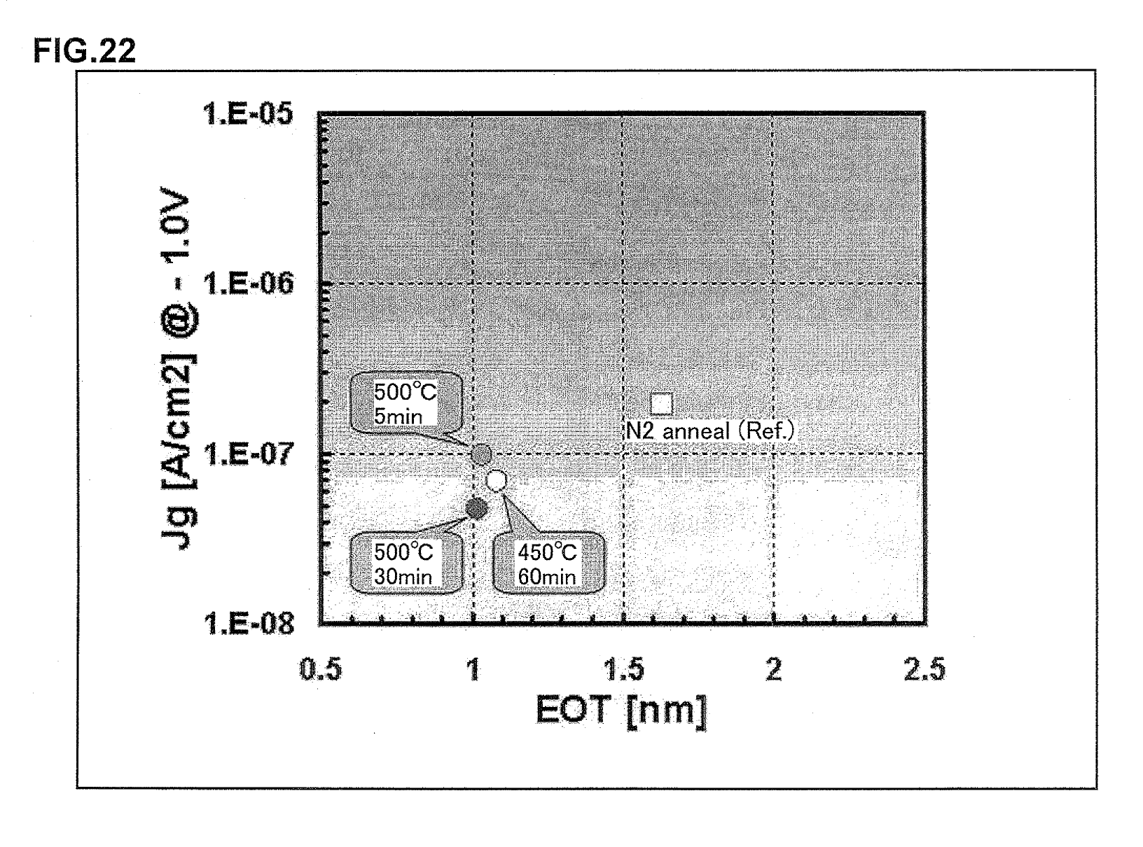

Further, FIG. 22 is a view showing the measurement results of the EOT and the leak current density of the ZrO film after the modification treatment (after the oxidation treatment) according to this example. In FIG. 22, EOT (nm) is taken on the horizontal axis, and the leak current density (A/cm²) is taken on the vertical axis. According to FIG. 22, it is found that the EOT and the lead current density are respectively smaller than those of the ZrO film of the reference example (shown by □) to which annealing is applied using N₂ gas, in any one of the ZrO film of the example (shown by lowermost) ◯) in which the wafer temperature during the modification treatment is set to 500° C. and the gas irradiation time is set to 30 minutes, and the ZrO film of the example (shown by uppermost ◯) in which the wafer temperature during the modification treatment is set to 500° C. and the gas irradiation time is set to 5 minutes, and the ZrO film of the example (shown by the intermediate) in which the wafer temperature during the modification treatment is set to 450° C. and the gas irradiation time is set to 60 minutes. Namely, it is found that oxidation of the ZrO film is surely performed by performing the aforementioned modification treatment using O₂ gas and H₂ gas.

Further, since these results are simultaneously obtained, it is found that different treatments (oxidation of the ZrO film and reduction of the TiN film) are simultaneously performed to the TiN film and the ZrO film respectively by performing the aforementioned modification treatment using O₂ gas and H₂ gas.

### Modified Example

In this embodiment, the modification treatment is performed using O₂ gas and H₂ gas. However, the present invention is not limited thereto, and a gas obtained by adding NH₃ gas to H₂ may also be used as the reductive gas (reducing agent), or NH₃ gas may be used as the reductive gas (reducing agent) instead of H₂ gas. By adding or using the NH₃ gas, being a nitriding gas (nitriding agent) as the reductive gas (reducing agent), separated titanium (Ti) atoms that exist in the TiN film can be nitrided when reducing the TiN film formed in the metal film forming step S40. Such a modified example will be described later as other embodiments (sixth and seventh embodiments).

Further, in this embodiment, gas supply systems of O₂ gas, H₂ gas, and NH₃ gas are respectively independently formed, so that these gases are supplied from a separate nozzle. However, the present invention is not limited thereto. For example, NH₃ gas and H₂ gas can be flowed together and can be supplied from the same nozzle. In this case, for example downstream ends of the gas supply tubes 232b and 232c may be joined. Further, O₂ gas and H₂ gas may be flowed together from the same nozzle. In this case, the downstream ends of the gas supply tubes 232e and 232c may be joined. Further, O₂ gas, NH₃ gas, and H₂ gas may be flowed together and supplied from the same nozzle. In this case, the downstream ends of the gas supply tubes 232e, 232b, and 232c may be joined. Particularly, the oxygen-containing gas and the hydrogen-containing gas can be efficiently activated by heating after mixing them. In addition, these gases may be flowed together and thereafter separated and supplied from a plurality of nozzles. The modified example will be described later as other embodiment (third embodiment).

Further, in the aforementioned embodiment, explanation is given for an example of forming the TiN film on the wafer 200 as the metal film. However, the present invention can also be applied to a case that any one of a titanium aluminum nitride film (TiAlN film), a titanium lantern nitride film (TiLaN film), a tantalum film (Ta film), a tantalum nitride film (TaN film), a ruthenium film (Ru film), a platinum film (Pt film), and a nickel film (Ni film), or a film obtained by adding impurities to these films so that contained atomic concentration is 10%, is formed on the wafer 200. Note that the TiAlN film and the TiLaN film are conductive metal composite films.

Further, in the aforementioned embodiment, explanation is given for an example that the ZrO film is formed on the wafer 200 as the insulating film. However, the present invention can also be applied to a case that other metal oxide film is formed on the wafer 200, with dielectric constant being 10 or more and film thickness being 200 nm or less, including metal elements such as hafnium (Hf), aluminum (Al), and titanium (Ti). Further, the present invention can also be applied to the modification treatment of a capacitor electrode having a lamination structure of an oxide such as ZrO film, a hafnium oxide film (HfO film), an aluminum oxide film (AlO) film, and a metal compound obtained by adding an element and mainly composed of the aforementioned oxide, and can also be applied to the modification treatment of a transistor gate structure. For example, the present invention can also be applied to a zirconium aluminum oxide film (ZrAlO film), a hafnium aluminum oxide film (HfAlO film), a zirconium silicate film (ZrSiO film), a hafnium silicate film (HfSiO film), or a laminated film of the aforementioned films, etc. Further, in the aforementioned embodiment, an example of the laminated film with an insulating film positioned on the metal film, has been explained. However, the present invention can also be applied to a laminated film with the insulating film sandwiched between metal films, and a laminated film with the metal film positioned on the insulating film, and so forth.

Further, in the aforementioned embodiment, explanation is given for a case that the substrate processing apparatus is constituted as a batch type vertical apparatus. However, the present invention is not limited thereto, and can also be applied to a single wafer substrate processing apparatus that processes the wafer 200 one by one, or processes several wafers 200 as a unit. Also, the present invention can be applied to a substrate processing apparatus that processes a plurality of wafers 200 simultaneously or sequentially, with wafers 200 arranged on the same plane. Such modified examples will also be described later as other embodiment (fifth embodiment).

### Second Embodiment of the Present Invention

This embodiment is a modified example of the first embodiment. In this embodiment, the oxygen-containing gas and the hydrogen-containing gas are alternately supplied to the wafer 200 on which the TiN film and the ZrO film are exposed or laminated, and the oxidation treatment of the ZrO film as a modification treatment shown in the first embodiment, and an individual modification treatment such as a reduction treatment of the TiN film, are sequentially executed. Thereafter, as a final step of the modification treatment, the oxygen-containing gas and the hydrogen-containing gas are simultaneously supplied to the wafer 200, to thereby simultaneously execute different modification treatments (oxidation of the ZrO film and reduction of the TiN film).

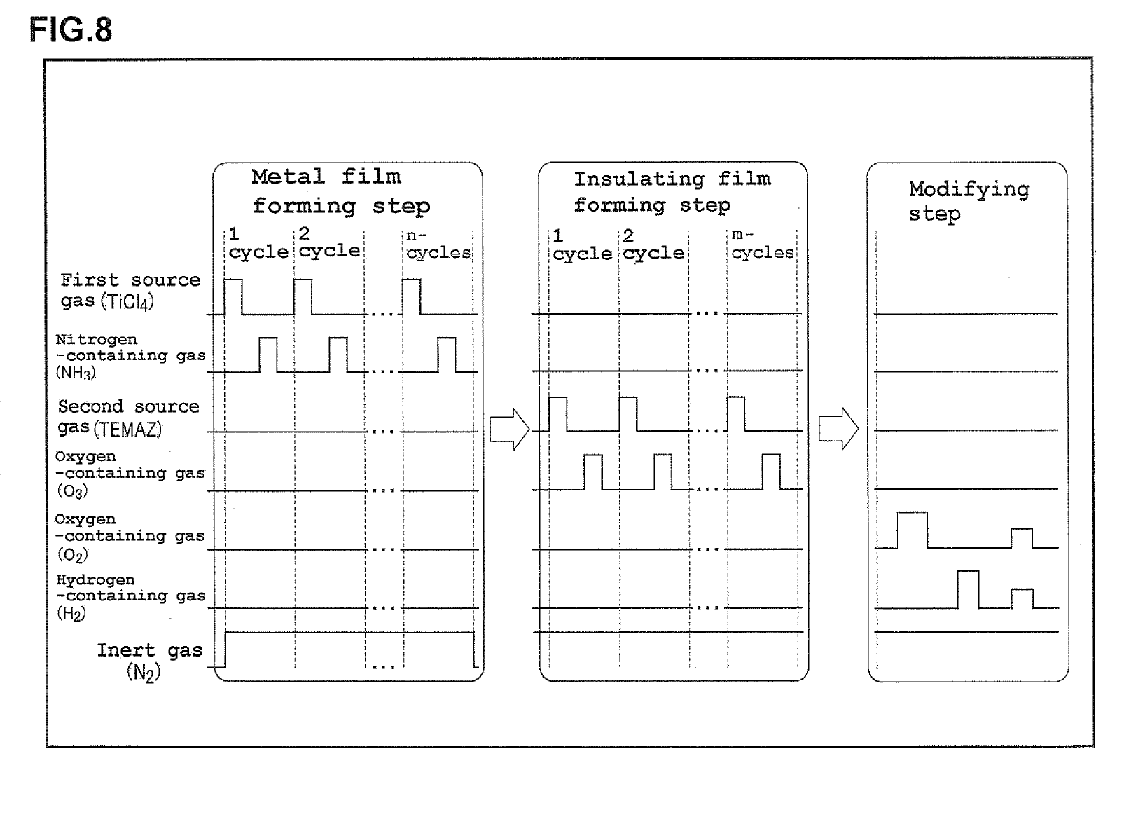

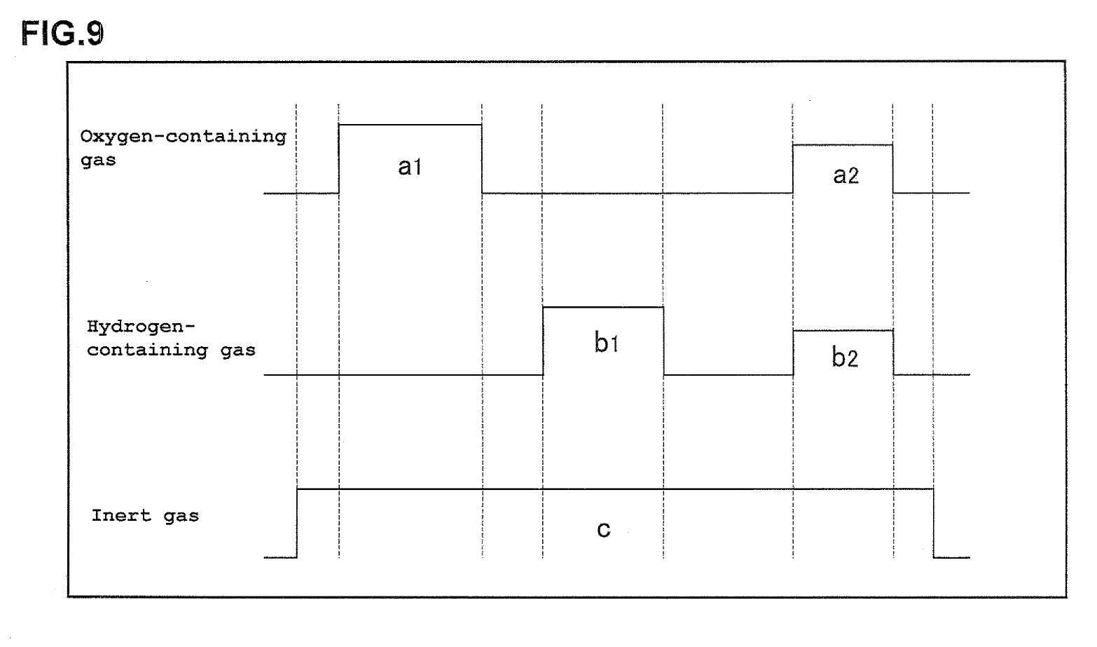

FIG. 8 is a timing chart of supplying gas in the substrate processing step according to this embodiment, and FIG. 9 is a timing chart of supplying gas in the modification treatment according to this embodiment.

In order to remove residual carbon, being an impurity in the ZrO film after executing the step similar to the steps S10 to S62 of the first embodiment, valves 243e and 244e of the gas supply tube 232e are opened, to thereby flow O₂ gas into the gas supply tube 232e. At this time, generation of O₃ gas by the ozonizer 500 is not performed. The O₂ gas is exhausted from the exhaust tube 231 while being supplied into the processing chamber 201 from the gas supply hole 250e of the nozzle 249e by a prescribed flow rate (a1), with its flow rate adjusted by the mass flow controller 241e (supply of O₂ gas). At this time, the valve 243j is simultaneously opened, and N₂ gas is flowed into the inert gas supply tube 232j. The N₂ gas is exhausted from the exhaust tube 231 while being supplied into the processing chamber 201 together with O₂ gas by a prescribed flow rate (c), with its flow rate adjusted by the mass flow controller 241j. Thus, the oxidation treatment is performed as the modification treatment process shown in the first embodiment.

Next, the inside of the processing chamber 201 is purged by N₂ gas, while maintain the supply of the prescribed flow rate (c) of the N₂ gas into the processing chamber 201, with the valves 243e, 244e closed and the valve 243j opened.

Next, in order to reduce the oxide layer formed on the TiN film, the valve 243c of the gas supply tube 232c is opened to thereby flow H₂ gas into the gas supply tube 232c. The H₂ gas is exhausted from the exhaust tube 231 while being supplied into the processing chamber 201 from the gas supply hole 250c of the nozzle 249c by a prescribed flow rate (b1), with its flow rate adjusted by the mass flow controller 241c (supply of H₂ gas). At this time, the valve 243h is simultaneously opened to thereby flow inert gas such as N₂ gas into the inert gas supply tube 232h. The N₂ gas flowing into the inert gas supply tube 232h, is exhausted from the exhaust tube 231 while being supplied into the processing chamber 201 together with H₂ gas by a prescribed flow rate, with its flow rate adjusted by the mass flow controller 241h. Thus, the reduction treatment is performed as the modification treatment process shown in the first embodiment. Note that when N₂ gas is supplied from the inert gas supply tube 232h by the flow rate (c), the valve 243j is closed and supply of the N₂ gas from the inert gas supply tube 232j is stopped, so that the N₂ gas is always continuously supplied into the processing chamber 201 by a constant flow rate (c).

Next, the inside of the processing chamber 201 is purged by the N₂ gas, while maintaining the supply of the N₂ gas into the processing chamber 201 by the prescribed flow rate (c), with the valve 243c closed and the valve 243h opened.

Next, H₂ gas and O₂ gas are simultaneously supplied into the processing chamber 201. Namely, O₂ gas is flowed into the gas supply tube 232e by opening the valves 243e and 244e of the gas supply tube 232e. At this time, generation of O₃ gas by the ozonizer 500 is not performed. The O₂ gas is exhausted from the exhaust tube 231 while being supplied into the processing chamber 201 from the gas supply hole 250e of the nozzle 249e by a prescribed flow rate (a2), with its flow rate adjusted by the mass flow controller 241e. Further, H₂ gas is flowed into the gas supply tube 232c by simultaneously opening the valve 243c of the gas supply tube 232c. The H₂ gas is exhausted from the exhaust tube 231 while being supplied into the processing chamber 201 from the gas supply hole 250c of the nozzle 249c by a prescribed flow rate (b2), with its flow rate adjusted by the mass flow controller 241c (supply of O₂ gas and H₂ gas). At this time, supply of a total flow rate (c) of the N₂ gas into the processing chamber 201 is maintained, with the valves 243j and 243h opened. Thus, as a final process, different modification treatments (oxidation treatment and reduction treatment) are simultaneously performed to the wafer 200 as the modification treatment process. Namely, oxidation of the ZrO film can be surely performed while suppressing the oxidation of the TiN film.

When simultaneous proceeding of the different modification treatments (oxidation treatment and reduction treatment) is completed, the inside of the processing chamber 201 is purged by N₂ gas, by maintaining the supply of the total flow rate (c) of the N₂ gas into the processing chamber 201, with the valves 243e, 244e, 243c closed and valves 243j and 243h opened. Thereafter, the step similar to the steps S70 to S90 of the first embodiment is executed.

In this embodiment as well, an effect similar to the aforementioned embodiment is exhibited. Note that in the modification treatment of this embodiment, the flow rate of O₂ gas and the flow rate of H₂ gas may be suitably changed. Namely, the flow rate (a1) for flowing O₂ gas alone and the flow rate (a2) for simultaneously flowing O₂ gas and H₂ are not limited to the same, but may be different. Further, the flow rate (b1) for flowing H₂ gas alone and the flow rate (b2) for simultaneously flowing H₂ gas and O₂ gas are not limited to the same but may be different.

### Third Embodiment of the Present Invention

In the first embodiment, O₂ gas and H₂ gas are respectively separately supplied from different gas supply tubes and different nozzles. Namely, O₂ gas and H₂ gas are individually heated in the nozzles 249e and 249c, and thereafter mixed in the processing chamber 201 for the first time. However, more effective activation can be achieved by heating O₂ gas and H₂ gas after mixing them. This embodiment is a modified example of the first embodiment based on such knowledge.

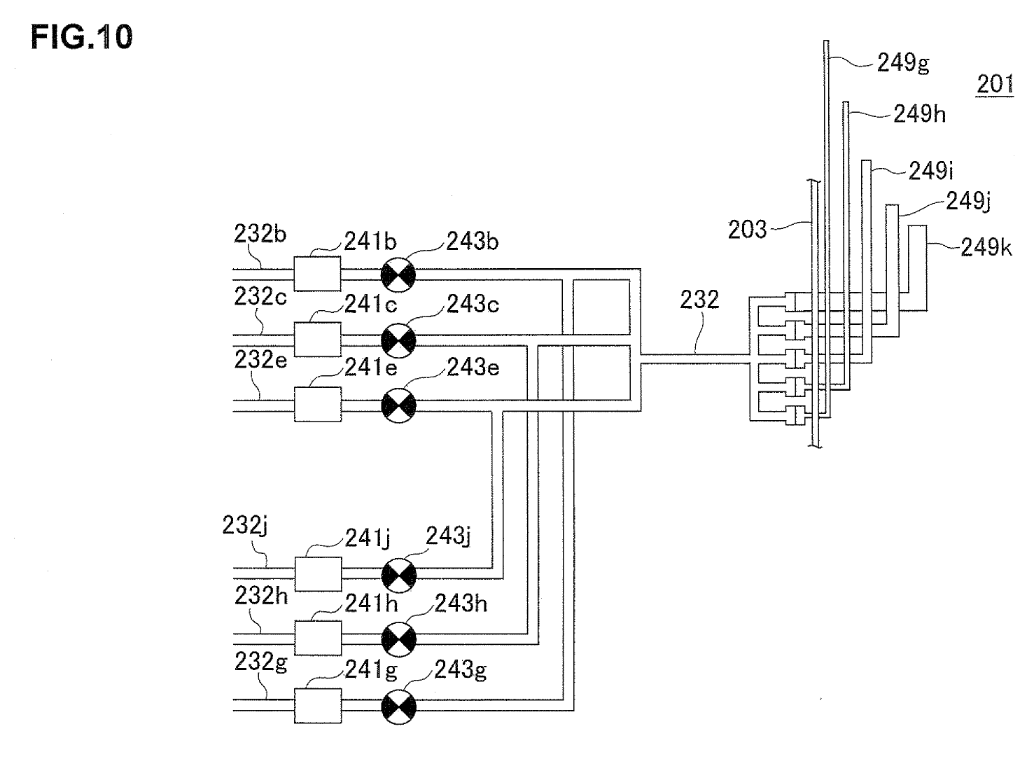

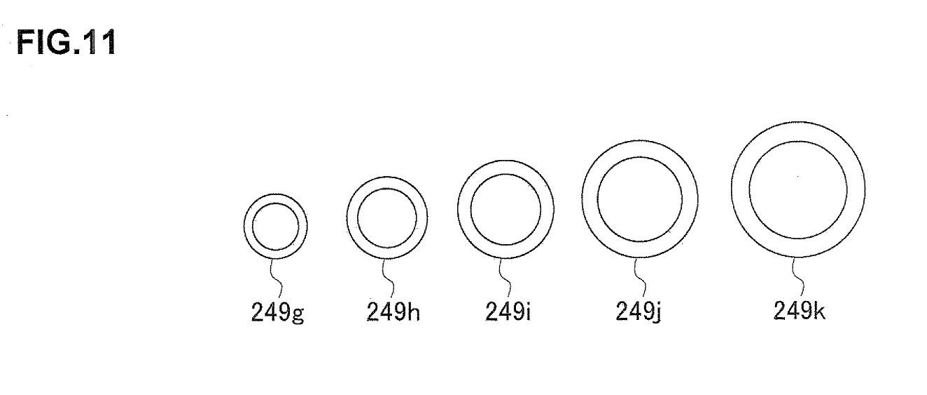

The structure of the gas supply system in this embodiment will be described using FIG. 10 and FIG. 11. FIG. 10 is a schematic block diagram of the gas supply system according to this embodiment. FIG. 11 is an upper side cross-sectional view of the nozzle according to this embodiment.

As shown in FIG. 10, the gas supply tubes 232b, 232c, 232e for supplying the oxygen-containing gas and the hydrogen-containing gas are previously joined before being introduced into the processing chamber 201, to become the gas supply tube 232. Namely, the gas supply tube 232 functions as a mixing chamber for previously mixing the oxygen-containing gas (such as O₂ gas) and the hydrogen-containing gas (such as H₂ gas and NH₃ gas) supplied into the processing chamber 201. Then, the gas supply tube 232 is branched again on the downstream side, so that downstream ends thereof are respectively connected to upstream ends of a plurality of nozzles 249g, 249H249i, 249j, and 249k. Openings are respectively provided on tip ends (downstream ends) of the nozzles 249g, 249H249i, 249j, and 249k. For example, in this embodiment, an amount of gas flowing into a furnace from each nozzle is respectively set to a desired value by adjusting an opening diameter, etc. For example, the amount of each gas is set to substantially equal to each other.

As a result of this structure, the oxygen-containing gas and the hydrogen-containing gas supplied from the gas supply tubes 232b, 232c, and 232e, are mixed in the gas supply tube, being the mixing chamber, to become a mixed gas. Then, the mixed gas is respectively supplied into the processing chamber 201 from each tip end of the nozzles 249g, 249h, 249i, 249j, and 249k. The mixed gas that reaches the inside of each of the nozzles 249g, 249h, 249i, 249j, and 249k, is heated in a process of moving upward in each nozzle. Namely, the oxygen-containing gas and the hydrogen-containing gas are mixed and thereafter heated. Thus, the oxygen-containing gas and the hydrogen-containing gas are more effectively activated, so that the oxidized species and the active species can be more effectively supplied to the surface of the wafer 200. As a result, a treatment speed of the modification treatment can be improved and productivity can be improved.

Further, in this embodiment, lengths and cross-sectional areas of the nozzles 249g, 249h, 249i, 249j, and 249k are respectively set to be different. Specifically, the lengths of the nozzles 249g, 249h, 249i, 249j, and 249k are sequentially shortened (see FIG. 10), and the cross-sectional areas thereof are sequentially increased (see FIG. 11). Namely, the cross-sectional area of a space inside of the nozzle with a short length, is larger than the cross-sectional area of the space in the nozzle with a long length. Thus, a gas travel time (travel time in the nozzle) of the mixed gas that reaches the inside of each of the nozzles 249g, 249h, 249i, 249j, and 249k, up to a time when they are respectively supplied into the processing chamber 201 from each tip end of the nozzle, can be substantially equalized, and uneven heating of the mixed gas can be suppressed. Then, an amount of the active species supplied into the processing chamber 201 can be equalized in each nozzle. Note that if the lengths of the nozzles 249g, 249h, 249i, 249j, and 249k are different, and the cross-sectional areas thereof are the same, the gas travel time in the nozzle is different depending on the length of each nozzle, thus generating the uneven heating depending on the position in a height direction in the processing chamber 201. However, as shown in this embodiment, a time lag in traveling in the nozzle can be reduced by changing the cross-sectional area according to the length of the nozzle. As a result, uniformity in wafers 200 during modification treatment can be improved.

### Modified Example

In this embodiment, the gas supply tubes 232b, 232c, 232e are joined. However, when H₂ is used alone as the reductive gas (reducing agent) (when NH₃ gas is not added), at least the gas supply tubes 232b and 232c may be joined and the gas supply tube 232e may not be joined. Further, when NH₃ gas is used alone as the reductive gas (reducing agent), at least the gas supply tubes 232b and 232e are joined and the gas supply tube 232c may not be joined. Further, the gas supply tubes 232a and 232d may also be joined and source gas may be supplied from the nozzles 249g, 249h, 249i, 249j, and 249k.

Further, in this embodiment, the gas supply tubes 232b, 232c, 232e are joined once to become the gas supply tube 232, and thereafter the gas supply tube 232 is branched again to supply the mixed gas to a plurality of nozzles 249g, 249h, 249i, 249j, and 249k. However, a gas supply tube having an individual mass flow controller may be prepared for each of the nozzles 249g, 249h, 249i, 249j, and 249k. Namely, the flow rate after branching the nozzle may be controlled for every nozzle. Further, the number of branched nozzles is not limited to five. Moreover, in this embodiment, the opening of the nozzle is provided only at the tip end. However, the gas supply hole may also be provided on the side face.

Further, the aforementioned nozzles 249g, 249h, 249i, 249j, and 249k can also be applied to the first embodiment. Namely, even in a case that the oxygen-containing gas and the hydrogen-containing gas are not mixed, the oxygen-containing gas and the hydrogen-containing gas may be supplied alone respectively, by a plurality of nozzles (corresponding to the nozzles 249g, 249h, 249i, 249j, 249k) with different shapes.

### Fourth Embodiment of the Present Invention

In the third embodiment, the gas supply tubes 232b, 232c, and 232e are joined once to become the gas supply tube 232, and the gas supply tube 232 is used as the mixing chamber. However, the present invention is not limited thereto. For example, a buffer chamber, being the mixing chamber, for previously mixing the oxygen-containing gas and the hydrogen-containing gas before supplying them into the processing chamber, may be provided inside of the reaction tube 203.

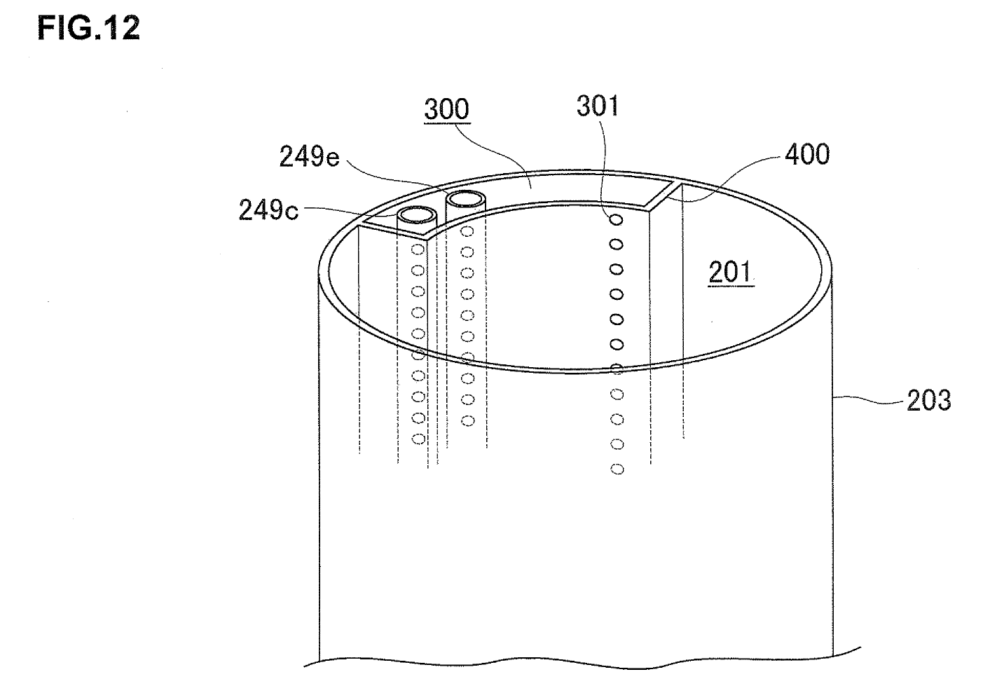

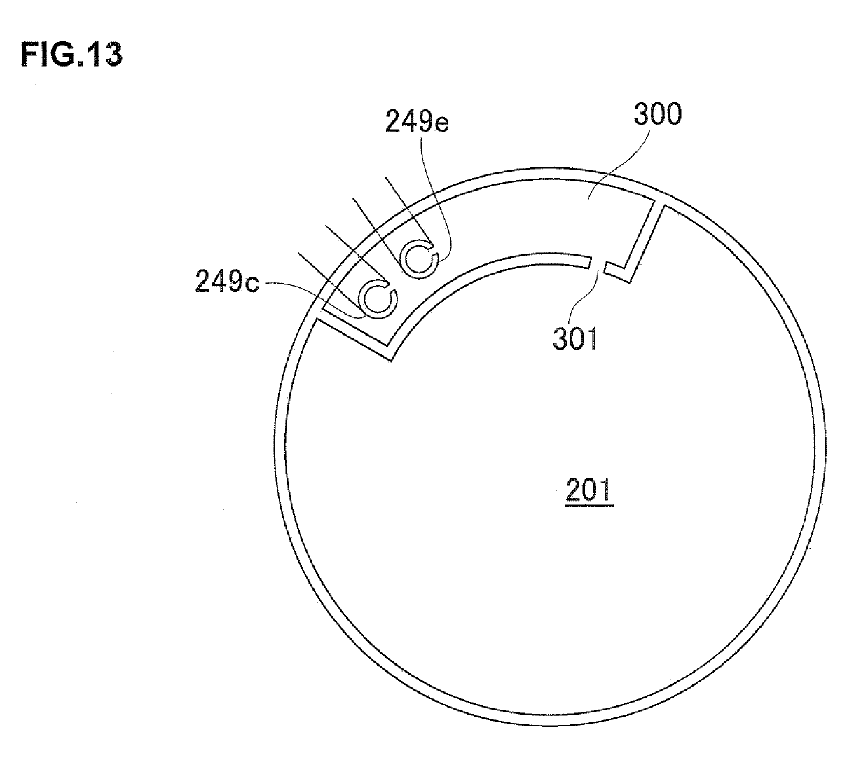

An internal structure of the reaction tube 203 according to this embodiment will be described using FIG. 12 and FIG. 13. FIG. 12 is a perspective expanded view of the reaction tube 203 according to this embodiment. FIG. 13 is an upper side cross-sectional view of the reaction tube 203 according to this embodiment.

In this embodiment, as shown in FIG. 12 and FIG. 13, a preheating chamber 300, being the buffer chamber, is formed in the reaction tube 203, so as to be partitioned from the processing chamber 201. A partition wall for forming the preheating chamber 300 is made of quartz for example. A plurality of gas supply holes 301 are opened at positions opposed to the wafer 200, on the side wall of the preheating chamber 300. At least the nozzles 249b and 249c are disposed in the preheating chamber 300. The oxygen-containing gas and the hydrogen-containing gas discharged from each nozzle are mixed in the preheating chamber 300, being the buffer chamber, and are supplied after being heated, to the wafer 200 from the gas supply holes 301 opposed to each wafer 200. Namely, the preheating chamber 300, being the buffer chamber, functions as the mixing chamber for previously mixing the oxygen-containing gas and the hydrogen-containing gas supplied into the processing chamber 201. By previously mixing the oxygen-containing gas and the hydrogen-containing gas in the preheating chamber 300, and sufficiently and uniformly heating them under a reduced pressure, a sufficient active species can be supplied when the aforementioned gases reach the surface of the wafer 200. As a result, a treatment speed of the modification treatment can be improved and the productivity can be improved.

Note that when the gas obtained by adding NH₃ gas to H₂ is used as the reductive gas (reducing agent), preferably the nozzle 249b is also disposed in the preheating chamber 300, in addition to the nozzles 249b and 249c. Further, when NH₃ gas is used alone as the reductive gas (reducing agent), at least the nozzles 249b and 249c are preferably disposed in the preheating chamber 300. The preheating chamber 300 can also be considered as a part of aforementioned each gas supply system.

### Fifth Embodiment of the Present Invention

Unlike the first embodiment, the substrate processing apparatus according to this embodiment is formed as a single wafer substrate processing apparatus that processes the wafer 200 one by one, or processes several wafers 200 as a unit in the modification treatment.

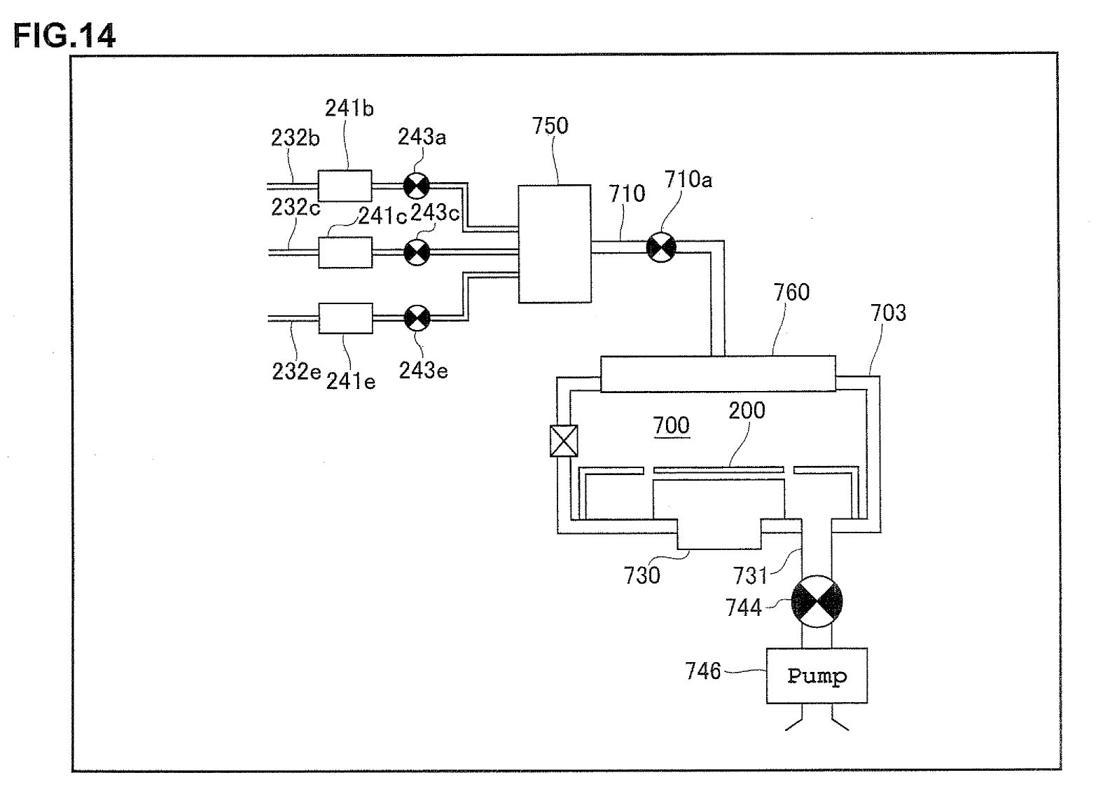

FIG. 14 shows the structure of an essential part of a single wafer substrate processing apparatus 702 used for the modification treatment in this embodiment. A susceptor 730 for holding one or a plurality of wafers 200 in a horizontal posture, is provided in a processing chamber 700. The susceptor 730 is formed so as to heat the wafer 200 to 400° C. or more for example by providing a heater not shown. A shower head 760 for mixing and uniformly dispersing the oxygen-containing gas and the hydrogen-containing gas, and supplying them like shower through a top plate, is provided in an upper part of the processing chamber 700.

The gas supply tubes 232a, 232b, 232c, 232d, and 232e described in the first embodiment, are respectively connected to the shower head 760 (note that in FIG. 14, figures of the gas supply tubes 232a, 232c, etc., are omitted for the convenience of explanation). As shown in FIG. 14, the gas supply tubes 232b, 232c, and 232e for supplying the oxygen-containing gas and the hydrogen-containing gas, are preferably introduced into a preheating chamber 750, being the mixing chamber, and are previously mixed therein. In this case, the oxygen-containing gas and the hydrogen-containing gas are preheated from 400° C. to 550° C. for example in the preheating chamber 750, and thereafter are introduced into the processing chamber 700 through a gas supply tube 710 and a valve 710a.

In this embodiment as well, an effect similar to the effect of the aforementioned embodiment is exhibited. Namely, since the oxygen-containing gas and the hydrogen-containing gas are mixed in the preheating chamber 750 and thereafter are preheated, the oxygen-containing gas and the hydrogen-containing gas can be more effectively activated, and the oxidized species and the active species can be more effectively supplied to the surface of the wafer 200. As a result, the treatment speed of the modification treatment can be improved and the productivity can be improved.

Note that in this embodiment, for example plasma can also be generated on the wafer 200 by supplying a high frequency power for example. Further, the oxygen-containing gas and the hydrogen-containing gas are activated by plasma in a separate chamber and thereafter the obtained oxidized species and the reductive species may be supplied to the surface of the wafer 200 by dispersion. In addition, a transparent top plate such as quartz may be disposed on the upper surface of the wafer 200, so that the wafer 200 can be irradiated with ultraviolet light and a vacuum-ultraviolet light through the top plate. Note that in order to generate the active species by heating the inside of the preheating chamber 750, the preheating chamber 750 needs to be heated to a temperature of 400° C. to 550° C. However, when the active species is generated by utilizing plasma or light, it is no problem in setting the temperature (preheating temperature) in the preheating chamber 750 to a further lower temperature. Further, this embodiment is not necessarily limited to a case that the gas supply tubes 232b, 232c, and 232d are provided in the preheating chamber 750, and they may be directly connected to the shower head 760.

### Sixth Embodiment of the Present Invention

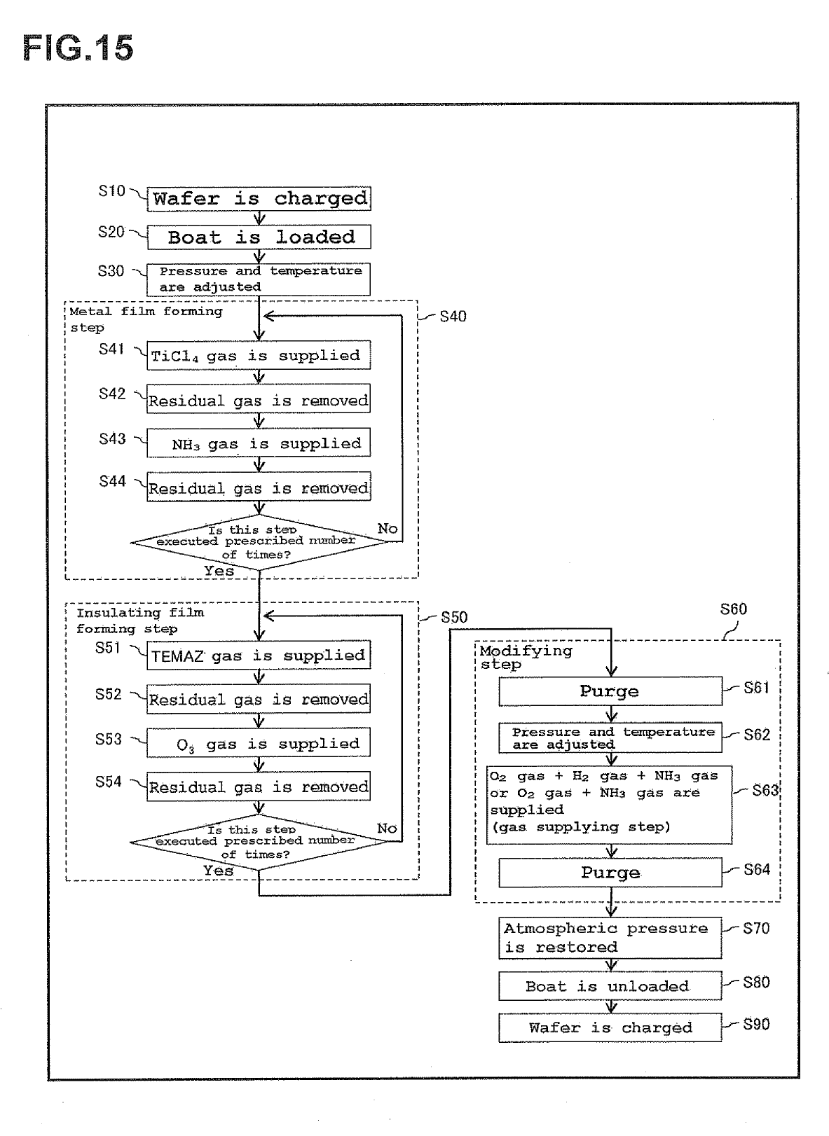

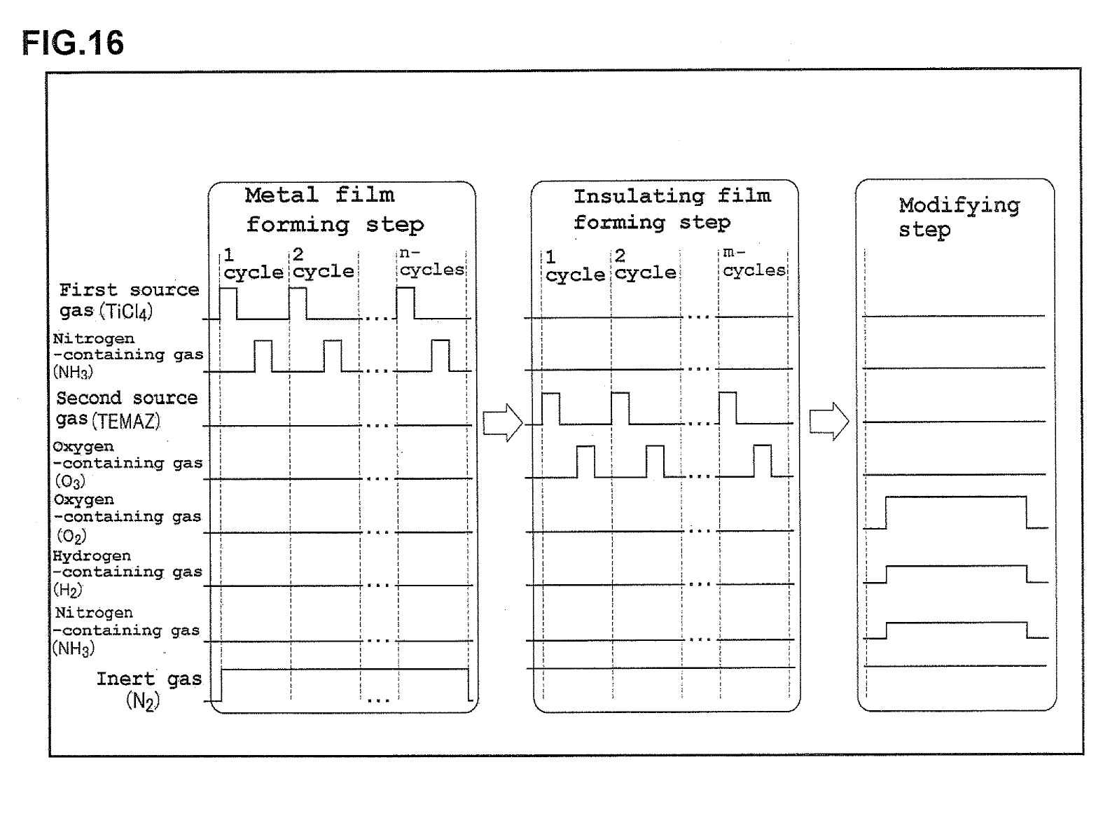

In the first embodiment, the modification treatment is performed using O₂ gas and H₂ gas. However, in this embodiment, a different point from the first embodiment is that the gas obtained by further adding NH₃ gas to H₂ is used as the reductive gas (reducing agent). The other point is similar to the first embodiment. FIG. 15 is a flowchart of the substrate processing steps including the modification treatment according to this embodiment, and FIG. 16 is a timing chart of supplying gas in the substrate processing step including the modification treatment according to this embodiment.

In this embodiment, the gas supplying step (S63) is executed for simultaneously executing different modification treatments (oxidation of the ZrO film and reduction and nitriding of the TiN film) by simultaneously supplying O₂ gas, H₂ gas, and NH₃ gas to the wafer 200, to remove the residual carbon, being the impurity in the ZrO film formed in the insulating film forming step S50, after executing the step similar to the steps S10 to S62 of the first embodiment.

Specifically, by the similar procedure as the procedure of the gas supplying step S63 of the first embodiment, O₂ gas and H₂ gas are supplied into the processing chamber 201, and simultaneously the valve 243b of the gas supply tube 232b is opened to thereby further supply NH₃ gas into the gas supply tube 232b. The NH₃ gas is exhausted from the exhaust tube 231 while being supplied into the processing chamber 201 from the gas supply hole 250b of the nozzle 249b, with its flow rate adjusted by the mass flow controller 241b (supply of O₂ gas+H₂ gas+NH₃ gas). At this time, the valve 243g is simultaneously opened to flow the inert gas such as N₂ gas into the inert gas supply tube 232g. The N₂ gas flowing into the inert gas supply tube 232g is exhausted from the exhaust tube 231 while being supplied into the processing chamber 201 together with NH₃ gas, with its flow rate adjusted by the mass flow controller 241g. Thus, different modification treatments (oxidation treatment and reduction treatment) are simultaneously performed as the modification treatment process shown in the first embodiment. Namely, oxidation of the ZrO film can be surely performed while suppressing the oxidation of the TiN film.

Further, by using the gas obtained by adding NH₃ gas to H₂ as the reductive gas (reducing agent), the TiN film formed by the metal film forming step S40 is reduced and a nitriding treatment for nitriding the TiN film is simultaneously in progress. Namely, since the NH₃ gas is the reductive gas (reducing agent) and also the nitriding gas (nitriding agent), nitrogen (N) atoms generated by activating or decomposing the NH₃ gas are bonded with bond-forming hands of liberated Ti atoms that exist in the TiN film, and Ti—N bond is formed, to thereby nitride the TiN film simultaneously in progress. Further, at this time, the TiN film is densified.

Here, similarly to the first embodiment, in order to simultaneously supply the oxygen-containing gas and the hydrogen-containing gas, start and stop of the gas supply are not necessarily identical to each other, and at least a part of each time for supplying O₂ gas, H₂ gas, and NH₃ gas into the processing chamber 201 may be overlapped. Namely, any one of the gases may be supplied first, or supply of any one of the gases is stopped and thereafter other gas may be flowed continuously.

When simultaneous progress of the different modification treatments (oxidation treatment, reduction treatment, and nitriding treatment) is completed, the inside of the processing chamber 201 is purged by N₂ gas, by maintaining supply of the N₂ gas into the processing chamber 201, with the valves 243e, 243c, 243b closed, and the valves 243j, 243h, and 243g opened. Thereafter, the step similar to the steps S64 to S90 of the first embodiment is executed.

According to this embodiment, an effect similar to the effect of the aforementioned embodiment is exhibited. Further, by using the NH₃ gas, being the nitriding gas (nitriding agent) as the reductive gas (reducing agent), the TiN film can be nitrided simultaneously while reducing the TiN film formed in the metal film forming step S40.

Note that in this embodiment, similarly to the first embodiment, explanation is given for a case that O₂ gas, H₂ gas, and NH₃ gas are simultaneously supplied. However, the present invention is not limited thereto. For example, similarly to the second embodiment, the present invention can also be suitably applied even in a case that O₂ gas and a mixed gas of H₂ gas and NH₃ gas are alternately supplied, or O₂ gas, H₂ gas, and NH₃ gas are sequentially supplied. Further, this embodiment can be combined with any one of the third to fifth embodiments or a plurality of them.

### Seventh Embodiment of the Present Invention

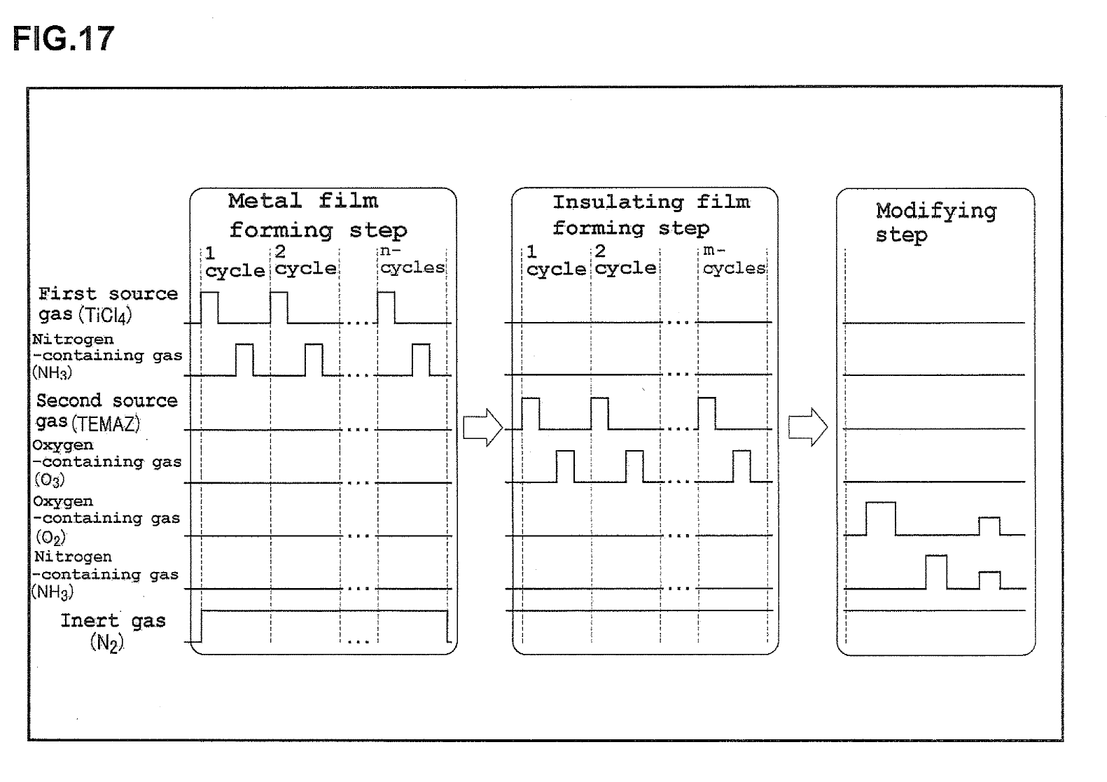

In the second embodiment, the modification treatment is performed using O₂ gas and H₂ gas. However, in this embodiment, a different point from the second embodiment is that NH₃ gas is used as the reductive gas (reducing agent) instead of H₂ gas. The other point is similar to the second embodiment. FIG. 15 is a flowchart of the substrate processing steps including the modification treatment according to this embodiment, and FIG. 17 is a timing chart of supplying gas in the substrate processing step including the modification treatment according to this embodiment.

In this embodiment, the step similar to the steps S10 to S62 of the first embodiment are executed, and thereafter O₂ gas and NH₃ gas are alternately supplied to the wafer 200, and an individual modification treatment such as oxidation treatment and reduction treatment is sequentially executed as the modification treatment process shown in the first embodiment. Thereafter, as the final step of the modification treatment, the gas supplying step (S63) of simultaneously supplying O₂ gas and NH₃ gas to the wafer 200, to thereby simultaneously execute different modification treatments (oxidation of the ZrO film and reduction of the TiN film), is executed.

Specifically, by the similar procedure as the procedure of the second embodiment, O₂ gas is supplied into the processing chamber 201 and is exhausted therefrom (supply of O₂ gas). Thus, the oxidation treatment is performed as the modification treatment process shown in the first embodiment.

Next, NH₃ gas is flowed into the gas supply tube 232b by opening the valve 243b of the gas supply tube 232b. The NH₃ gas is exhausted from the exhaust tube 231 while being supplied into the processing chamber 201 from the gas supply hoe 250b of the nozzle 249b by a prescribed flow rate, with its flow rate adjusted by the mass flow controller 241b (supply of NH₃ gas). At this time, the valve 243g is simultaneously opened to flow the inert gas such as N₂ gas into the inert gas supply tube 232g. The N₂ gas flowing into the inert gas supply tube 232g is exhausted from the exhaust tube 231 while being supplied into the processing chamber 201 together with NH₃ gas, with its flow rate adjusted by the mass flow controller 241g. Thus, the reduction treatment is performed as the modification treatment process shown in the first embodiment. Further, by using the NH₃ gas, being the nitriding gas (nitriding agent) as the reductive gas (reducing agent), the nitriding treatment for nitriding the TiN film is also simultaneously in progress. Namely, nitriding of the TiN film is in progress in such a way that nitrogen (N) atoms generated by activating or decomposing NH₃ gas, are bonded with the bond-forming hands of liberated Ti atoms that exist in the TiN film, to thereby form Ti—N bond. Further, at this time, the TiN film is densified.

Next, by the similar procedure as the procedure of the second embodiment, the inside of the processing chamber 201 is purged.

Next, O₂ gas and NH₃ gas are simultaneously supplied into the processing chamber 201 by opening the valves 243e, 244e, and 243b. Thus, as the final treatment, different modification treatments (oxidation treatment, reduction treatment, and nitriding treatment) are simultaneously performed to the wafer 200 as the modification treatment process. Namely, oxidation of the ZrO film can be surely performed while suppressing the oxidation of the TiN film. Further, nitriding of the TiN film can be surely performed.

When the modification is completed, the inside of the processing chamber 201 is purged by N₂ gas, by maintaining supply of the total flow rate of the N₂ gas into the processing chamber 201, with the valves 243e, 244e, and 243b closed and the valves 243j and 243g opened. Thereafter, the step similar to the steps S64 to S90 of the first embodiment is executed.

According to this embodiment, an effect similar to the effect of the aforementioned embodiment is exhibited. Further, the TiN film formed in the metal film forming step S40 can be nitrided by using the NH₃ gas containing nitrogen, being the nitriding gas (nitriding agent) as the reductive gas (reducing agent).

Note that in this embodiment, explanation is given for a case that O₂ gas and the NH₃ gas are alternately supplied similarly to the second embodiment. However, the present invention is not limited thereto. For example, the present invention can also be suitably applied to a case that O₂ gas and NH₃ gas are simultaneously supplied similarly to the first embodiment. Further, this embodiment can be arbitrarily combined with any one of the aforementioned third embodiment to the fifth embodiment or a plurality of them.

### Eighth Embodiment of the Present Invention

As described above, in order to simultaneously supply the oxygen-containing gas and the hydrogen-containing gas, start and stop of the gas supply are not necessarily identical to each other, and at least a part of each time for supplying the oxygen-containing gas and the hydrogen-containing gas into the processing chamber 201 may be overlapped. Namely, only other gas may be supplied alone first, and supply of one of the gases is stopped, and thereafter the other gas may be flowed alone.

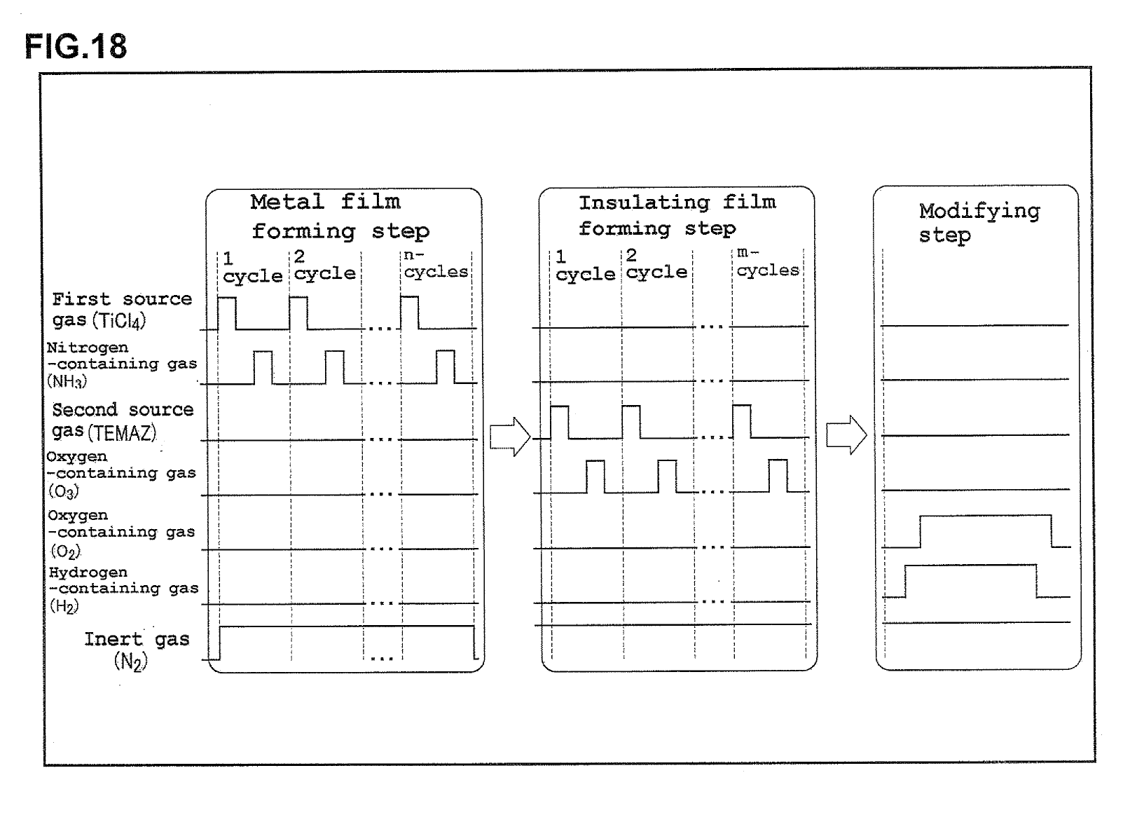

Therefore, in this embodiment, supply of H₂ gas, being the hydrogen-containing gas, is started earlier than the supply of O₂ gas, being the oxygen-containing gas, and supply of H₂ gas is stopped earlier than the supply of O₂ gas. FIG. 18 is a timing chart of supplying gas of the substrate processing step including the modification treatment according to this embodiment.

In this embodiment as well, an effect similar to the effect of the aforementioned embodiment is exhibited. Note that excessive progress of the oxidation treatment can be suppressed by starting the supply of H₂ gas before supplying O₂ gas and setting the inside of the processing chamber 201 in H₂ gas atmosphere. Further, the oxidation treatment can be surely performed by continuing the supply of O₂ gas after stopping the supply of H₂ gas.

### Other Embodiment of the Present Invention

As described above, embodiments of the present invention are specifically described. However, the present invention is not limited to the aforementioned embodiments, and can be variously modified in a range not departing from the gist of the invention.

For example, in the aforementioned embodiment, explanation is given for a case that two or more kinds of thin films having mutually different elemental components are laminated. However, the present invention is not limited thereto, and can also be suitably applied to a case that two kinds or more thin films are not laminated but are exposed respectively.

Further, for example in the aforementioned embodiment, O₂ gas, being the oxygen-containing gas, is used as the oxidizing gas (oxidizing agent). However, the present invention is not limited thereto, and other oxygen-containing gas such as O₃ gas, H₂O gas, and a mixed gas of O₂ gas and H₂ gas or the gas obtained by arbitrarily combining them can also be used as the oxidizing gas (oxidizing agent). When O₃ gas is used instead of O₂ gas, there is a possibility that the TiN film of the lower layer can also be oxidized by setting the flow rate excessively. However, O₃ gas is more useful if the oxide film of the upper layer is hardly oxidized like the AlO film. Accordingly, it is also effective to change the gas species of the oxygen-containing gas depending on the kind of a film while selecting a suitable flow rate.

Further, for example in the aforementioned embodiment, formation of the laminated film of the metal film such as TiN film and the insulating film such as ZrO film on the wafer 200, and different modification treatments applied to each of the TiN film and the ZrO film, are continuously performed using the same treating furnace 202 (in-situ). However, a different treating furnace can also be used. For example, it may be also acceptable to form the TiN film and the ZrO film using the treating furnace different from the aforementioned treating furnace 202, and thereafter perform different modification treatments simultaneously to each of the TiN film and the ZrO film.

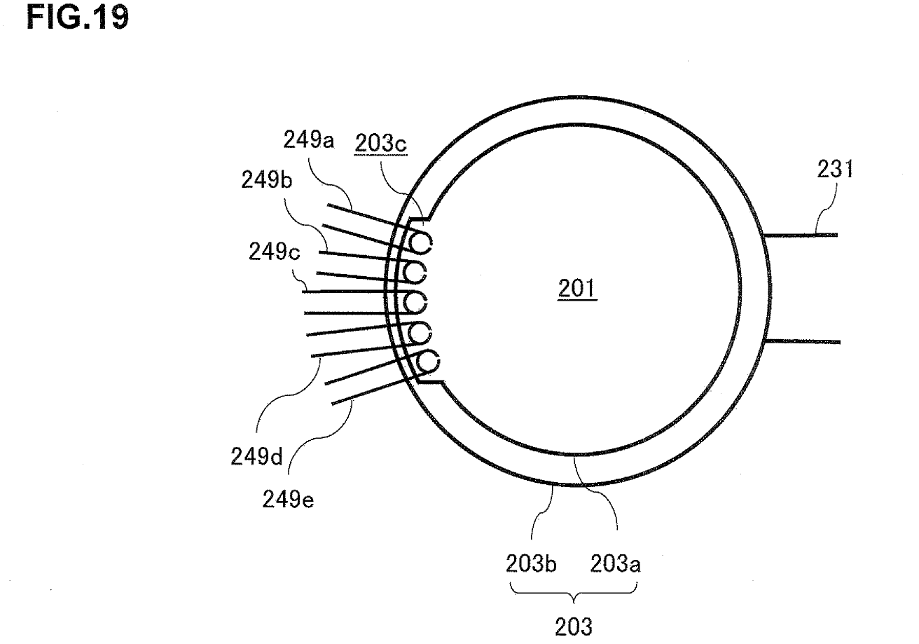

In the treating furnace of the aforementioned embodiment, the reaction tube 203 is formed as a double tube. However, the present invention is not limited thereto. For example, as shown in the cross-sectional view of FIG. 19, the reaction tube 203 may be formed by a cylindrical inner tube 203a with the processing chamber 201 formed inside, and an outer tube 203b arranged concentric with the inner tube 203a outside the inner tube 203a so as to surround the inner tube 203a, with an upper end closed and a lower end opened. At this time, a spare chamber 203c may also be provided on an inner wall of the inner tube 203a as the mixing chamber. The oxygen-containing gas and the hydrogen-containing gas supplied from the nozzles 249b, 249c, and 249e, can be previously mixed before supplying them into the processing chamber 201 and thereafter the mixed gas can be heated. Further, gas flow flowing in parallel through a plurality of wafers 200 can be easily formed by providing an exhaust port at a position opposed to the spare chamber 203c of the inner tube 203a, and exhausting between the outer tube 203b and the inner tube 203a.

Further, in the aforementioned embodiment, explanation is given for an example of a sequence of forming the film (metal film and insulating film) having a stoichiometric composition. However, a film having a composition different from the stoichiometric composition may also be formed. For example, in the NH₃ gas supplying step S43 in the metal film forming step S40 and/or the O₃ gas supplying step S53 in the insulating film forming step S50, the nitriding reaction of the Ti-containing layer and/or the oxidation reaction of the Zr-containing layer may be caused so as not to be saturated. For example, when several atomic layers of Ti layer and/or Zr layer are formed in the TiCl₄ gas supplying step S41 and/or the TEMAZ gas supplying step S51, at least a part of its surface layer (1 atomic layer of the surface) is nitrided and/or oxidized. Namely, a part or an entire part of its surface layer is nitrided and/or oxidized. In this case, nitriding and/or oxidation is in progress under a condition that the nitriding reaction of the Ti layer and/or the oxidation reaction of the Zr layer is not saturated, so that an entire body of several atomic layers of Ti layer and/or Zr layer is not nitrided and/or oxidized. Note that several layers under the surface layer of several atomic layers of Ti layer can also be nitrided and several layers under the surface layer of several atomic layers of Zr layer can also be oxidized, depending on the condition. However, it is preferable to nitride and/or oxidize only the surface layer, because controllability of a composition ratio of the TiN film and/or the ZrO film can be improved. Further, for example when the Ti layer and/or the Zr layer of 1 atomic layer or less than 1 atomic layer is formed in the TiCl₄ gas supplying step S41 and/or the TEMAZ gas supplying step S51, a part of the Ti layer is nitrided and/or a part of the Zr layer is oxidized. In this case as well, nitriding and/or oxidizing is performed under the condition that the nitriding reaction of the Ti layer and/or the oxidation reaction of the Zr layer is not saturated, so that the entire body of the Ti layer of 1 atomic layer or less than 1 atomic layer is not nitrided and/or the entire body of the Zr layer of 1 atomic layer or less than 1 atomic layer is not oxidized. Note that nitrogen and/or oxygen is an element that does not become solid by itself.

At this time, the pressure or the pressure and a gas supply time in the processing chamber 201 in the TiCl₄ gas supplying step S41 and/or the TEMAZ gas supplying step S51, are set to be larger or longer than the pressure or the pressure and the gas supply time in the processing chamber 201 in the processing chamber 201 in the TiCl₄ gas supplying step S41 and/or the TEMAZ gas supplying step S51 in a case that the TiN film and/or the ZrO film having the stoichiometric composition is formed. By thus controlling the processing condition, the supply amount of Ti and/or Zr in the TiCl₄ gas supplying step S41 and/or the TEMAZ gas supplying step S51 is set to be more excessive than a case that the TiN film and/or the ZrO film having the stoichiometric composition is formed. Then, the nitriding reaction of the Ti-containing layer and/or the oxidation reaction of the Zr-containing layer is not saturated in the NH₃ gas supplying step S43 and/or the O₃ gas supplying step S53, due to excessive supply of Ti and/or Zr in the TiCl₄ gas supplying step S41 and/or the TEMAZ gas supplying step S51. Namely, the number of Ti atoms and/or Zr atoms given in the TiCl₄ gas supplying step S41 and/or the TEMAZ gas supplying step S51 are set to be more excessive than a case that the TiO film and/or the ZrO film having the stoichiometric composition is formed, thus suppressing the nitriding reaction of the Ti-containing layer and/or the oxidation reaction of the Zr-containing layer in the NH₃ gas supplying step S43 and/or the O₃ gas supplying step S53. Thus, the composition ratio of the TiN film is controlled so that titanium (Ti) is more excessive than nitrogen (N) in the stoichiometric composition, and the composition ratio of the ZrO film is controlled so that zirconium (Zr) is more excessive than oxygen (O) in the stoichiometric composition.

Alternatively, the pressure or the pressure and the gas supply time in the processing chamber 201 in the NH₃ gas supplying step S43 and/or the O₃ gas supplying step S53, are set to be smaller or shorter than the pressure or the pressure and the gas supply time in the processing chamber 201 in the processing chamber 201 in the NH₃ gas supplying step S43 and/or the O₃ gas supplying step S53 in a case that the TiN film and/or the ZrO film having the stoichiometric composition is formed. By thus controlling the processing condition, the supply amount of nitrogen and/or oxygen in the NH₃ gas supplying step S43 and/or the O₃ gas supplying step S53 is set to be more insufficient than a case that the TiN film and/or the ZrO film having the stoichiometric composition is formed. Then, the nitriding reaction of the Ti-containing layer and/or the oxidation reaction of the Zr-containing layer is not saturated in the NH₃ gas supplying step S43, due to insufficient supply of nitrogen and/or oxygen in the NH₃ gas supplying step S43 and/or the O₃ gas supplying step S53. Namely, the number of nitrogen atoms and/or oxygen atoms given in the NH₃ gas supplying step S43 and/or the O₃ gas supplying step S53 are set to be more insufficient than a case that the TiO film and/or the ZrO film having the stoichiometric composition is formed, thus suppressing the nitriding reaction of the Ti-containing layer and/or the oxidation reaction of the Zr-containing layer in the NH₃ gas supplying step S43 and/or the O₃ gas supplying step S53. Thus, the composition ratio of the TiN film is controlled so that titanium (Ti) is more excessive than nitrogen (N) in the stoichiometric composition, and the composition ratio of the ZrO film is controlled so that zirconium (Zr) is more excessive than oxygen (O) in the stoichiometric composition.

<Preferable Aspect of the Present Invention>

Preferable aspect of the present invention will be supplementarily described hereafter.

According to an aspect of the present invention, there is provided a method for manufacturing a semiconductor device, comprising:

exposing a substrate on which two or more kinds of thin films having mutually different elemental components are laminated or exposed, to oxygen-containing gas and hydrogen-containing gas simultaneously or alternately; and

simultaneously performing different modification treatments to the thin films respectively.

According to other aspect of the present invention, there is provided a method for manufacturing a semiconductor device, comprising:

exposing a substrate on which two or more kinds of thin films having mutually different elemental components are laminated or exposed, to oxygen-containing gas and hydrogen-containing gas simultaneously or alternately; and

simultaneously performing different modification treatments to an interface between the laminated thin films and each of the thin films that constitutes the interface.

Preferably, the substrate is simultaneously exposed to the oxygen-containing gas and the hydrogen-containing gas after the substrate is exposed to the oxygen-containing gas and the hydrogen-containing gas alternately.

Further preferably, two or more kinds of thin films are a metal film and an insulating film directly formed on the metal film.

Further preferably, when the substrate is exposed to the oxygen-containing gas and the hydrogen-containing gas simultaneously, the oxygen-containing gas and the hydrogen-containing gas are supplied into a processing chamber after previously mixing them in a mixing chamber provided outside a processing chamber in which the substrate is housed.

According to other aspect of the present invention, there is provided a method for manufacturing a semiconductor device, comprising:

Simultaneously or alternately supplying oxygen-containing gas and hydrogen-containing gas into a processing chamber in which a substrate is housed, the substrate having two or more kinds of thin films having mutually different elemental components exposed or laminated; and

unloading the substrate from the processing chamber.

wherein in supplying the gases, different modification treatments are simultaneously performed to the thin films respectively.

According to further other aspect of the present invention, there is provided a method for manufacturing a semiconductor device, comprising:

supplying oxygen-containing gas and hydrogen-containing gas simultaneously or alternately into a processing chamber in which a substrate is housed, the substrate having two or more kinds of thin films having mutually different elemental components exposed or laminated; and

unloading the substrate from the processing chamber,

wherein in supplying the gases, different modification treatments are simultaneously performed to an interface between the laminated thin films and each of the thin films that constitutes the interface.

Preferably, when the oxygen-containing gas and the hydrogen-containing gas are simultaneously supplied in supplying the gases, the oxygen-containing gas and the hydrogen-containing gas are supplied into the processing chamber after previously mixing them in a mixing chamber provided outside the processing chamber.

Preferably, one of the modification treatments that is performed simultaneously, is oxidation treatment and the other one is a reduction treatment or a nitriding treatment.

Preferably, in executing modification, at least any one of oxygen, hydrogen, or ammonium is introduced, and different modifications are simultaneously performed to a laminated film by irradiation of any one of heat, plasma or ultraviolet light or vacuum-ultraviolet light.

Preferably, the laminated film, being a treatment object, is composed of a metal film and an insulating film.

Preferably, the metal film is any one of TiN film, TiAlN film, and TaN film, and the insulating film is made of a material whose dielectric constant exceeds 8.

According to further other aspect of the present invention, there is provided a substrate processing apparatus, comprising:

a processing chamber in which a substrate is housed, the substrate having two or more kinds of thin films having mutually different elemental components exposed or laminated;

a gas supply system configured to supply oxygen-containing gas and hydrogen-containing gas into the processing chamber;

an exhaust system configured to exhaust inside of the processing chamber; and

a controller configured to control at least the gas supply system and the exhaust system,

wherein the controller is configured to control the gas supply system so that the oxygen-containing gas and the hydrogen-containing gas are simultaneously or alternately supplied into the processing chamber in which the substrate is housed, and different modification treatments are simultaneously performed to the thin films respectively.

Preferably, the gas supply system comprises a mixing chamber configured to previously mix the oxygen-containing gas and the hydrogen-containing gas before supplying them into the processing chamber, wherein when the oxygen-containing gas and the hydrogen-containing gas are simultaneously supplied into the processing chamber, the oxygen-containing gas and the hydrogen-containing gas are previously mixed in the mixing chamber and thereafter are supplied into the processing chamber.

Further preferably, inside of the mixing chamber can be heated.

Further preferably, the gas supply system comprises a plurality of nozzles with different lengths configured to supply previously mixed oxygen-containing gas and hydrogen-containing gas into the processing chamber, wherein in the plurality of nozzles, a cross-sectional area of a space in a nozzle with a short length is set to be larger than a cross-sectional area of a space in a nozzle with a long length.

Further preferably, the gas supply system comprises a plurality of nozzles with different lengths configured to supply previously mixed oxygen-containing gas and hydrogen-containing gas into the processing chamber, wherein the plurality of nozzles are formed so that a travel time of the oxygen-containing gas and the hydrogen-containing gas in each nozzle required for supplying them into the processing chamber, is set to be substantially the same.

Further preferably, in the exhaust system, pressure in the processing chamber after mixing the gases can be set to 10000 Pa or less, upon introducing oxygen and hydrogen into the processing chamber.

Further preferably, in the processing chamber, formation of two or more kinds of thin films on the substrate having mutually different elemental components, and different modification treatments applied to each of the thin film by simultaneously or alternately supplying oxygen-containing gas and hydrogen-containing gas, can be continuously executed.

According to further other aspect of the present invention, there is provided a method for manufacturing a semiconductor device, comprising:

simultaneously or alternately supplying oxygen-containing gas and hydrogen-containing gas to a substrate on which two or more kinds of thin films having mutually different elemental components are exposed or laminated,

wherein in supplying the gases, different modification treatments are simultaneously performed to the thin films respectively.

According to further other aspect of the present invention, there is provided a method for manufacturing a semiconductor device, comprising:

simultaneously or alternately supplying oxygen-containing gas and hydrogen-containing gas to a substrate on which two or more kinds of thin films having mutually different elemental components are laminated,

wherein in supplying the gases, different modification treatments are simultaneously performed to an interface between the laminated thin films and each of the thin films that constitutes the interface.

Preferably, after alternately supplying the oxygen-containing gas and the hydrogen-containing gas to the substrate, the oxygen-containing gas and the hydrogen-containing gas are further simultaneously supplied thereto, to thereby end the treatment.

Further preferably, two or more kinds of thin films having mutually different elemental components include an insulating film, and a dielectric constant of the insulating film after modification treatment is 10 or more, and a film thickness of the insulating film is 200 nm or less.

Further preferably, two or more kinds of thin films having mutually different elemental components include a metal film, and the metal film is the film made of a material of any one of TiN, TiAlN, TiLaN, Ta, TaN, Ru, Pt, and Ni, or the film made of a material obtained by adding an impurity into the film so that a containing atomic concentration is 10% or less.

According to further other aspect of the present invention, there is provided a substrate processing apparatus, comprising:

a processing chamber in which a substrate is housed, the substrate having two or more kinds of thin films having mutually different elemental components exposed or laminated;

a gas supply system configured to supply oxygen-containing gas and hydrogen-containing gas into the processing chamber;

an exhaust system configured to exhaust inside of the processing chamber; and

a controller configured to control at least the gas supply system and the exhaust system,

wherein the controller is configured to control the gas supply system so that the oxygen-containing gas and the hydrogen-containing gas are simultaneously or alternately supplied into the processing chamber in which the substrate is housed, and different modification treatments are simultaneously performed to the thin films respectively, and is configured to control the exhaust system so that a pressure in the processing chamber is 10000 Pa or less when either the oxygen-containing gas or the hydrogen-containing gas is supplied into the processing chamber.

Preferably, the controller is configured to independently control supply timings of the oxygen-containing gas and hydrogen-containing gas by the gas supply system respectively.

Further preferably, there is provided at least any one of a heating mechanism of heating the substrate housed in the processing chamber or the oxygen-containing gas and the hydrogen-containing gas supplied into the processing chamber, a plasma generating mechanism of activating the oxygen-containing gas and the hydrogen-containing gas supplied into the processing chamber by plasma, and a ultraviolet light irradiation mechanism of irradiating the substrate housed in the processing chamber or the oxygen-containing gas and the hydrogen-containing gas supplied into the processing chamber, with a ultraviolet light or a vacuum-ultraviolet light.

Further preferably, the gas supply system comprises a mixing chamber configured to previously mix oxygen-containing gas and hydrogen-containing gas before the oxygen-containing gas and the hydrogen-containing gas are supplied into the processing chamber, and comprises at least any one of a preheating mechanism of heating the mixing chamber, a preliminary plasma generation mechanism of activating the oxygen-containing gas and the hydrogen-containing gas supplied into the mixing chamber by plasma, and a preliminary ultraviolet light irradiation mechanism of irradiating the oxygen-containing gas and the hydrogen-containing gas supplied into the mixing chamber with a ultraviolet light or a vacuum-ultraviolet light.

Further preferably, the processing chamber is formed so that a plurality of substrates can be housed, and a difference in a route length from mixing the oxygen-containing gas and the hydrogen-containing gas up to each substrate, or a difference in a route length from at least any one of heating, activation by plasma, and irradiation of a ultraviolet light or a vacuum-ultraviolet light applied to the oxygen-containing gas and the hydrogen-containing gas, up to each substrate is not more than a diameter of the substrate.

Further preferably, the processing chamber is formed so that 3 or more and 200 or less substrates can be housed in a state of being arranged at prescribed intervals in a vertical direction in a horizontal posture respectively.

Further preferably, the gas supply system comprises a plurality of nozzles with different lengths configured to supply previously mixed oxygen-containing gas and hydrogen-containing gas into the processing chamber, wherein in the plurality of nozzles, a cross-sectional area of a space in a nozzle with a short length is set to be larger than a cross-sectional area of a space in a nozzle with a long length.

According to further other aspect of the present invention, there is provided a semiconductor device, comprising:

two or more kinds of thin films having mutually different elemental components laminated or exposed on a substrate,

wherein different modification treatments are simultaneously performed to the thin films respectively by simultaneously or alternately exposing the two or more kinds of thin films to oxygen-containing gas and hydrogen-containing gas respectively.

Preferably, the two or more kinds of thin films having mutually different elemental components, include an insulating film, and a dielectric constant of the insulating film after modification treatment is 10 or more, and a film thickness of the insulating film after modification treatment is 200 nm or less.

Further preferably, the two or more kinds of thin films having mutually different elemental components include an insulating film, and a dielectric constant of the insulating film after modification treatment is 8 or more, and a film thickness of the insulating film after modification treatment is 0.05 nm or less in a silicon oxide film reduced thickness.

Further preferably, the two or more kinds of thin films having mutually different elemental components include an insulating film, and a dielectric constant of the insulating film after modification treatment is 15 or more, and a film thickness of the insulating film after modification treatment is 0.05 nm or less in a silicon oxide film reduced thickness.

Further preferably, the two or more kinds of thin films having mutually different elemental components include a metal film, and the metal film is the film made of a material of any one of TiN, TiAlN, TiLaN, Ta, TaN, Ru, Pt, and Ni, or the film made of a material obtained by adding an impurity into the film so that a containing atomic concentration is 10% or less.

### DESCRIPTION OF SIGNS AND NUMERALS

101 Substrate processing apparatus
121 Controller
200 Wafer (substrate)
201 Processing chamber
600 TiN film (insulating film)
601 ZrO film (metal film)

What is claimed is:

1. A method for manufacturing a semiconductor device, comprising:
exposing a substrate on which two or more kinds of thin films having mutually different elemental components are laminated or exposed, to oxygen-containing gas and hydrogen-containing gas simultaneously or alternately; and
simultaneously performing different modification treatments to the thin films respectively.

2. A method for manufacturing a semiconductor device, comprising:
exposing a substrate on which two or more kinds of thin films having mutually different elemental components are laminated or exposed, to oxygen-containing gas and hydrogen-containing gas simultaneously or alternately; and
simultaneously performing different modification treatments to an interface between the laminated thin films and each of the thin films that constitutes the interface.

3. The method of claim 1, wherein after alternately exposing the substrate to the oxygen-containing gas and the hydrogen-containing gas, the substrate is simultaneously exposed to the oxygen-containing gas and the hydrogen-containing gas.

4. The method of claim 1, wherein the two or more kinds of thin films are a metal film and an insulating film directly formed on the metal film.

5. The method of claim 1, wherein when the substrate is simultaneously exposed to the oxygen-containing gas and the hydrogen-containing gas, the oxygen-containing gas and the hydrogen-containing gas are previously mixed in a mixing chamber provided outside a processing chamber in which the substrate is housed, and thereafter are supplied into the processing chamber.

6. A substrate processing apparatus, comprising:
a processing chamber in which a substrate is housed, the substrate having two or more kinds of thin films having mutually different elemental components exposed or laminated;
a gas supply system configured to supply oxygen-containing gas and hydrogen-containing gas into the processing chamber;
an exhaust system configured to exhaust inside of the processing chamber; and
a controller configured to control at least the gas supply system and the exhaust system,
wherein the controller is configured to control the gas supply system so that the oxygen-containing gas and the hydrogen-containing gas are simultaneously or alternately supplied into the processing chamber in which the substrate is housed, and different modification treatments are performed to the thin films respectively.

7. The substrate processing apparatus of claim 6, comprising:
a mixing chamber configured to previously mix the oxygen-containing gas and the hydrogen-containing gas before supplying them into the processing chamber,
wherein when the oxygen-containing gas and the hydrogen-containing gas are simultaneously supplied into the processing chamber, the oxygen-containing gas and the hydrogen-containing gas are previously mixed in the mixing chamber, and thereafter are supplied into the processing chamber.

8. The substrate processing apparatus of claim 6, comprising:
a plurality of nozzles with different lengths configured to supply previously mixed oxygen-containing gas and hydrogen-containing gas into the processing chamber,
wherein in the plurality of nozzles, a cross-sectional area of a space in a nozzle with a short length is formed larger than a cross-sectional area of a space in a nozzle with a long length.

9. The substrate processing apparatus of claim 6, comprising:
a plurality of nozzles with different lengths configured to supply previously mixed oxygen-containing gas and hydrogen-containing gas into the processing chamber,
wherein the plurality of nozzles are formed so that a travel time of a mixed gas of the oxygen-containing gas and the hydrogen-containing gas required for supplying them into the processing chamber, is set to be substantially the same.

10. A semiconductor device, comprising:
a substrate on which two or more kinds of thin films having mutually different elemental components are laminated or exposed,
wherein the two or more kinds of thin films are simultaneously or alternately exposed to oxygen-containing gas and hydrogen-containing gas, to thereby simultaneously perform different modification treatments to the thin films respectively.
